(19) United States
(12) Patent Application Publication
(10) Pub. No.: US 2024/0195384 A1
(43) Pub. Date: Jun. 13, 2024

(54) MULTIPLE MEMBRANE THICKNESS WAFERS USING LAYER TRANSFER ACOUSTIC RESONATORS AND METHOD OF MANUFACTURING SAME

(71) Applicant: Murata Manufacturing Co., Ltd., Nagaokakyo-shi (JP)

(72) Inventors: Douglas JACHOWSKI, Santa Barbara, CA (US); Patrick TURNER, Portola Valley, CA (US); Chris O'BRIEN, Goleta, CA (US)

(21) Appl. No.: 18/524,193

(22) Filed: Nov. 30, 2023

Related U.S. Application Data
(60) Provisional application No. 63/430,715, filed on Dec. 7, 2022.

(51) Int. Cl. H03H 9/17; H03H 3/02; H03H 9/02; H03H 9/13; H03H 9/205

(52) U.S. Cl. CPC H03H 9/174; H03H 3/02; H03H 9/02228; H03H 9/13; H03H 9/205; H03H 2003/023

(57) ABSTRACT

An acoustic resonator is provided that includes a substrate; a first piezoelectric layer having first and second surfaces that oppose each other, with the second surface coupled to the substrate directly or via one or more intermediate layers; a second piezoelectric layer having first and second opposing surfaces, with the first surface coupled to the first surface of the first piezoelectric layer and opposite to the substrate; an etch stop layer disposed between the respective first surfaces of the first and second piezoelectric layers; and first and second interdigital transducers (IDTs) on at least one of the first and second piezoelectric layers, respectively. Moreover, a portion of one of the first and second piezoelectric layers is removed between the second surface of the respective piezoelectric layer and the etch stop.

### CROSS REFERENCE TO RELATED APPLICATIONS

The current application claims priority to U.S. Patent Provisional Application No. 63/430,715, filed Dec. 7, 2022, the entire contents of which are hereby incorporated by reference.

### TECHNICAL FIELD

This disclosure relates to radio frequency filters using acoustic wave resonators having multiple membrane thicknesses and a method for manufacturing the same.

### BACKGROUND

A radio frequency (RF) filter is a two-port device configured to pass some frequencies and to stop other frequencies, where “pass” means transmit with relatively low signal loss and “stop” means block or substantially attenuate. The range of frequencies passed by a filter is referred to as the “passband” of the filter. The range of frequencies stopped by such a filter is referred to as the “stop-band” of the filter. A typical RF filter has at least one passband and at least one stop-band. Specific requirements on a passband or stop-band may depend on the specific application. For example, in some cases a “passband” may be defined as a frequency range where the insertion loss of a filter is better than a defined value such as 1 dB, 2 dB, or 3 dB, while a “stop-band” may be defined as a frequency range where the rejection of a filter is greater than a defined value such as 20 dB, 30 dB, 40 dB, or greater depending on application.

RF filters are used in communications systems where information is transmitted over wireless links. For example, RF filters may be found in the RF front ends of cellular base stations, mobile telephone and computing devices, satellite transceivers and ground stations, IoT (Internet of Things) devices, laptop computers and tablets, fixed point radio links, and other communications systems. RF filters are also used in radar and electronic and information warfare systems.

Performance enhancements to the RF filters in a wireless system can have a broad impact to system performance. Improvements in RF filters can be leveraged to provide system performance improvements, such as larger cell size, longer battery life, higher data rates, greater network capacity, lower cost, enhanced security, higher reliability, etc. These improvements can be realized at many levels of the wireless system both separately and in combination, for example, at the RF module, RF transceiver, mobile or fixed sub-system, or network levels. As the demand for RF filters operating at higher frequencies continues to increase, there is a need for improved filters that can operate at different frequency bands while also improving the manufacturing processes for making such filters.

### SUMMARY

In general, an important parameter that determines the resonance frequency of a transversely-excited film bulk acoustic resonator (XBAR) is the thickness of the diaphragm or piezoelectric material that is over a cavity and/or the overall thickness of the resonator stack. However, existing techniques for fabricating an XBAR configuration with different membrane thicknesses currently lead to different elevations on a wafer surface, which leads to degrading resonator performance with undesirable resonator characteristics.

Thus, according to an exemplary aspect, an XBAR is provided that can be fabricated with different membrane thicknesses using layer transfer for improved resonator performance. In an exemplary aspect, an acoustic resonator is provided that includes a substrate; a first piezoelectric layer having first and second surfaces that oppose each other, with the second surface facing the substrate and coupled thereto directly or via one or more intermediate layers; a second piezoelectric layer having first and second opposing surfaces, with the first surface coupled to the first surface of the first piezoelectric layer and opposite to the substrate; an etch stop layer disposed between the respective first surfaces of the first and second piezoelectric layers; and first and second interdigital transducers (IDTs) on at least one of the first and second piezoelectric layers, respectively. In this aspect, a portion of the first piezoelectric layers is removed between the second surface of the first piezoelectric layer and the etch stop.

In another exemplary aspect of the acoustic resonator, the one or more intermediate layers comprise one or more dielectric layers, and at least a pair of cavities extend partially into the one or more dielectric layers.

In another exemplary aspect of the acoustic resonator, the first piezoelectric layer extends over each of the pair of cavities.

In another exemplary aspect of the acoustic resonator, the first IDT is disposed on the second piezoelectric layer where the portion of the first piezoelectric layer is removed.

In another exemplary aspect of the acoustic resonator, the portion of the first piezoelectric layer that is removed overlaps and faces one of the pair of cavities in a thickness direction of the acoustic resonator.

In another exemplary aspect of the acoustic resonator, the first and second IDTs form a pair of acoustic resonators having different resonance frequencies. In this aspect, the first and second piezoelectric layers and the first and second IDTs are configured such that radio frequency signals applied to each IDT excites a primarily shear acoustic mode in the first and second piezoelectric layers, respectively.

In another exemplary aspect of the acoustic resonator, the first piezoelectric layer comprises a material with a first cut having a first crystallographic orientation, and the second piezoelectric layer comprises a material with a second cut having a second crystallographic orientation that is different than the first crystallographic orientation.

In another exemplary aspect, the acoustic resonator further includes at least one dielectric layer on at least one of the first and second piezoelectric layers. In one aspect, the at least one dielectric layer is disposed on and in between interleaved fingers of each of the first and second IDTs, with a thickness of the at least one dielectric layer on the first IDT being different than the at least one dielectric layer on the second IDT. In another aspect, the at least one dielectric layer is disposed on each of the first and second piezoelectric layers and on a side thereof that is opposite to the first and second IDTs, respectively, with a thickness of the at least one dielectric layer on the first piezoelectric layer being different than the at least one dielectric layer on the second first piezoelectric layer.

In another exemplary aspect of the acoustic resonator, the first and second IDTs are both disposed on the second surface of the second piezoelectric layer.

In another exemplary aspect, the acoustic resonator includes at least one bonding layer disposed between the first and second IDTs and the at least one of the first and second piezoelectric layers, respectively. Moreover, in an aspect, the at least one bonding layer comprises the etch stop layer.

In another exemplary, an acoustic resonator is provided that includes a substrate; a first piezoelectric layer attached to the substrate via one or more intermediate layers, the piezoelectric layer comprising one or more first acoustic resonators; a second piezoelectric layer attached to the first piezoelectric layer opposite the substrate and comprising one or more second acoustic resonators; a first dielectric layer on the first piezoelectric layer; a second dielectric layer on the second piezoelectric layer; first and second interdigital transducers (IDTs) at the first and second piezoelectric layers, respectively; and an etch stop layer disposed between the first and second piezoelectric layers. In this aspect, a portion of the first piezoelectric layer is removed between the substrate and the etch stop.

In another exemplary, a radio frequency module is provided that includes a filter device including a plurality of acoustic resonators; and a radio frequency circuit coupled to the filter device, the filter device and the radio frequency circuit being enclosed within a common package. In this aspect, at least one of the plurality of acoustic resonators of the filter device includes a substrate; a first piezoelectric layer having first and second surfaces that oppose each other, with the second surface facing the substrate and coupled thereto directly or via one or more intermediate layers; a second piezoelectric layer having first and second opposing surfaces, with the first surface coupled to the first surface of the first piezoelectric layer and opposite to the substrate; an etch stop layer disposed between the respective first surfaces of the first and second piezoelectric layers; and first and second interdigital transducers (IDTs) on at least one of the first and second piezoelectric layers, respectively. Moreover, a portion of the first piezoelectric layer is removed between the second surface of the first piezoelectric layer and the etch stop.

The above simplified summary of example aspects serves to provide a basic understanding of the present disclosure. This summary is not an extensive overview of all contemplated aspects and is intended to neither identify key or critical elements of all aspects nor delineate the scope of any or all aspects of the present disclosure. Its sole purpose is to present one or more aspects in a simplified form as a prelude to the more detailed description of the disclosure that follows. To the accomplishment of the foregoing, the one or more aspects of the present disclosure include the features described and exemplarily pointed out in the claims.

### BRIEF DESCRIPTION OF THE DRAWINGS

The accompanying drawings, which are incorporated into and form a part of this specification, illustrate one or more example aspects of the present disclosure and, together with the detailed description, serve to explain their principles and implementations.

FIG. 1A includes a schematic plan view and two schematic cross-sectional views of a transversely-excited film bulk acoustic resonator (XBAR).

FIG. 1B shows a schematic cross-sectional view of an alternative configuration of an XBAR.

FIG. 2A is an expanded schematic cross-sectional view of a portion of the XBAR of FIG. 1A.

FIG. 2B is an expanded schematic cross-sectional view of an alternative configuration of the XBAR of FIG. 1A.

FIG. 2C is an expanded schematic cross-sectional view of another alternative configuration of the XBAR of FIG. 1A.

FIG. 2D is an expanded schematic cross-sectional view of another alternative configuration of the XBAR of FIG. 1A.

FIG. 2E is an expanded schematic cross-sectional view of a portion of a solidly-mounted XBAR (SM XBAR).

FIG. 3A is a schematic cross-sectional view of an XBAR according to an exemplary aspect.

FIG. 3B is an alternative schematic cross-sectional view of an XBAR according to an exemplary aspect.

FIG. 4 is a graphic illustrating a shear horizontal acoustic mode in an XBAR.

FIG. 5A is a schematic block diagram of a filter using XBARs of FIGS. 1A and/or 1B.

FIG. 5B is a schematic diagram of a radio frequency module that includes an acoustic wave filter device according to an exemplary aspect.

FIG. 6 is a schematic cross-sectional view of two XBAR devices with different membrane thicknesses according to an exemplary aspect.

FIG. 7 is a flow chart of a process for fabricating an XBAR according to an exemplary aspect.

FIG. 8 is a flow chart of a process for fabricating an XBAR with different membrane thicknesses according to an exemplary aspect.

FIG. 9 is a schematic cross-sectional view of improved XBAR resonators formed on the same die with different membrane thicknesses using a layer transfer subprocess according to an exemplary aspect.

FIG. 10 is a flow chart of a first process for fabricating an XBAR with different membrane thicknesses using a layer transfer subprocess according to an exemplary aspect.

FIG. 11 is a flow chart of a second process for fabricating an XBAR with different membrane thicknesses using a layer transfer subprocess according to an exemplary aspect.

FIG. 12 is a schematic cross-sectional view of improved XBAR resonators formed on the same die with different membrane thicknesses according to an exemplary aspect.

FIG. 13 is a flow chart of a third process for fabricating an XBAR with different membrane thicknesses using a layer transfer subprocess according to an exemplary aspect.

FIG. 14 is a flow chart of a fourth process for fabricating an XBAR with different membrane thicknesses using a layer transfer subprocess according to an exemplary aspect.

FIG. 15 is a schematic cross-sectional view of an alternative XBAR resonator formed on the same die with different membrane thicknesses using either the first process of FIG. 13 or the second process of FIG. 14 according to an exemplary aspect.

FIG. 16 is a flow chart of an alternative process for fabricating an XBAR with different membrane thicknesses using a layer transfer subprocess according to an exemplary aspect.

FIGS. 17A-17Q are diagrams illustrating cross-sectional views of an XBAR for fabricating the XBAR resonators on the same die with different membrane thicknesses using the layer transfer subprocess of FIG. 16 according to an exemplary aspect.

Throughout this description, elements appearing in figures are assigned three-digit or four-digit reference designators, where the two least significant digits are specific to the element and the one or two most significant digits are the figure number where the element is first introduced. An element that is not described in conjunction with a figure may be presumed to have the same characteristics and function as a previously described element having the same reference designator.

### DETAILED DESCRIPTION

Various aspects of the disclosed acoustic resonator, filter device and method of manufacturing the same are now described with reference to the drawings, wherein like reference numerals are used to refer to like elements throughout. In the following description, for purposes of explanation, numerous specific details are set forth in order to promote a thorough understanding of one or more aspects of the disclosure. It may be evident in some or all instances, however, that any aspects described below can be practiced without adopting the specific design details described below. In other instances, well-known structures and devices are shown in block diagram form in order to facilitate description of one or more aspects. The following presents a simplified summary of one or more aspects of the invention in order to provide a basic understanding thereof.

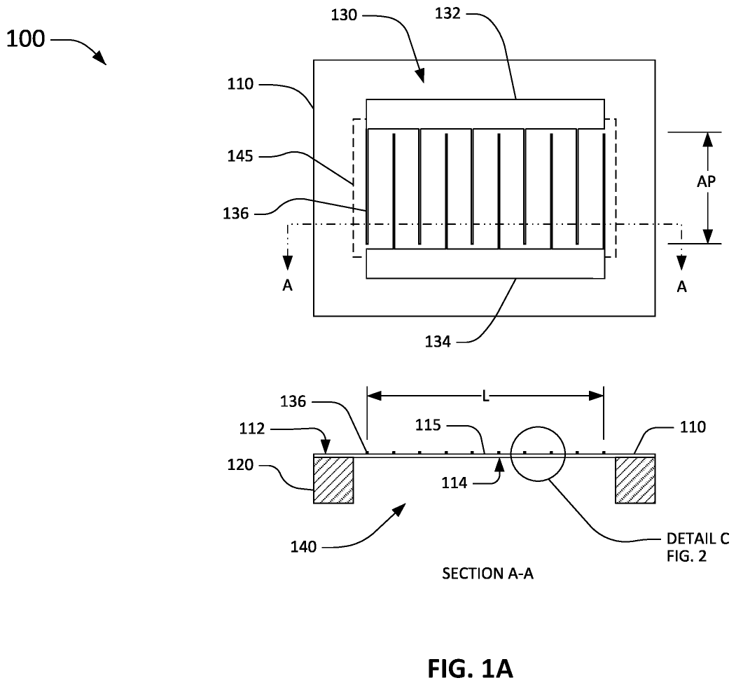

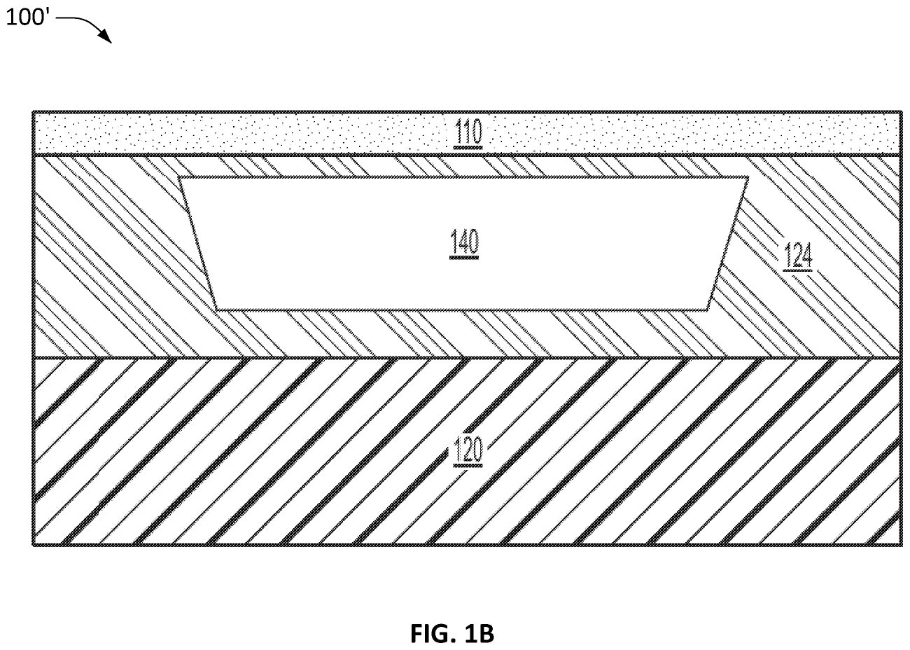

FIG. 1A shows a simplified schematic top view and orthogonal cross-sectional views of an acoustic resonator device, namely a transversely excited film bulk acoustic resonator (XBAR) 100. XBAR resonators, such as the resonator 100, may be used in a variety of RF filters including band-reject filters, band-pass filters, duplexers, and multiplexers. XBARs are particularly suited for use in filters for communications bands with frequencies above 3 GHZ.

In general, the XBAR 100 is made up of a thin film conductor pattern formed at one or both surfaces of a piezoelectric layer 110 (herein piezoelectric plate or piezoelectric layer may be used interchangeably) having parallel front side 112 and a back side 114, respectively (also referred to generally first and second surfaces, respectively). It should be appreciated that the term “parallel” generally refers to the front side 112 and back side 114 being opposing to each other and that the surfaces are not necessarily planar and parallel to each other. For example, to the manufacturing variances result from the deposition process, the front side 112 and back side 114 may have undulations of the surface as would be appreciated to one skilled in the art.

According to an exemplary aspect, the piezoelectric layer is a thin single-crystal layer of a piezoelectric material, such as lithium niobate, lithium tantalate, lanthanum gallium silicate, gallium nitride, or aluminum nitride. It should be appreciated that the term “single-crystal” does not necessarily mean entirely of a uniform crystalline structure and may include impurities due to manufacturing variances as long as the crystal structure is within acceptable tolerances. The piezoelectric layer is cut such that the orientation of the X, Y, and Z crystalline axes with respect to the front and back sides is known and consistent. In the examples described herein, the piezoelectric layers are Z-cut, which is to say the Z axis is normal to the front and back sides 112, 114. However, XBARs may be fabricated on piezoelectric layers with other crystallographic orientations including rotated Z-cut, Z-cut and rotated YX cut.

The Y-cut family, such as 120Y and 128Y, are typically referred to as 120YX or 128YX, where the “cut angle” is the angle between the y axis and the normal to the layer. The “cut angle” is equal to β+90°. For example, a layer with Euler angles [0°, 30°, 0° ] is commonly referred to as “120° rotated Y-cut” or “120Y.” Thus, the Euler angles for 120YX and 128YX are (0, 120-90,0) and (0, 128-90,0) respectively. A “Z-cut” is typically referred to as a ZY cut and is understood to mean that the layer surface is normal to the Z axis but the wave travels along the Y axis. The Euler angles for ZY cut are (0, 0, 90).

The back side 114 of the piezoelectric layer 110 may be at least partially supported by a surface of the substrate 120 except for a portion of the piezoelectric layer 110 that forms a diaphragm 115 that is over (e.g., spanning or extending over) a cavity 140 in one or more layers below the piezoelectric layer 110, such as one or more intermediate layers above or in the substrate. In other words, the back side 114 of the piezoelectric layer 110 can be coupled or connected either directly or indirectly, via one or more intermediate layers (e.g., a dielectric layer), to a surface of the substrate 120. Moreover, the phrase “supported by” or “attached” may, as used herein interchangeably, mean attached directly, attached indirectly, mechanically supported, structurally supported, or any combination thereof. The portion of the piezoelectric layer that is over (e.g., spanning or extending over) the cavity can be referred to herein as a “diaphragm” 115 due to its physical resemblance to the diaphragm of a microphone. As shown in FIG. 1, the diaphragm 115 is contiguous with the rest of the piezoelectric layer 110 around all of a perimeter 145 of the cavity 140. In this context, “contiguous” means “continuously connected without any intervening item”. However, the diaphragm 115 can be configured with at least 50% of the edge surface of the diaphragm 115 coupled to the edge of the piezoelectric layer 110 in an exemplary aspect.

According to the exemplary aspect, the substrate 120 is configured to provide mechanical support to the piezoelectric layer 110. The substrate 120 may be, for example, silicon, sapphire, quartz, or some other material or combination of materials. The back side 114 of the piezoelectric layer 110 may be bonded to the substrate 120 using a wafer bonding process. Alternatively, the piezoelectric layer 110 may be grown on the substrate 120 or supported by, or attached to, the substrate in some other manner.

For purposes of this disclosure, “cavity” has its conventional meaning of “an empty space within a solid body.” The cavity 140 may be a hole completely through the substrate 120 (as shown in Section A-A), a hole within a dielectric layer (as shown in FIG. 1B), or a recess in the substrate 120. The cavity 140 may be formed, for example, by selective etching of the substrate 120 before or after the piezoelectric layer 110 and the substrate 120 are attached, either directly or indirectly.

As shown, the conductor pattern of the XBAR 100 includes an interdigital transducer (IDT) 130. The IDT 130 includes a first plurality of parallel fingers, such as finger 136, extending from a first busbar 132 and a second plurality of fingers extending from a second busbar 134. The first and second pluralities of parallel fingers are interleaved with each other. At least a portion of the interleaved fingers overlap for a distance AP, commonly referred to as the “aperture” of the IDT. The center-to-center distance L between the outermost fingers of the IDT 130 is the “length” of the IDT.

In the example of FIG. 1A, the IDT 130 is at the surface of the front side 112 (e.g., the first surface) of the piezoelectric layer 110. However, as discussed below, in other configurations, the IDT 130 may be at the surface of the back side 114 (e.g., the second surface) of the piezoelectric layer 110 or at both the surfaces of the front and back sides 112, 114 of the piezoelectric layer 110, respectively.

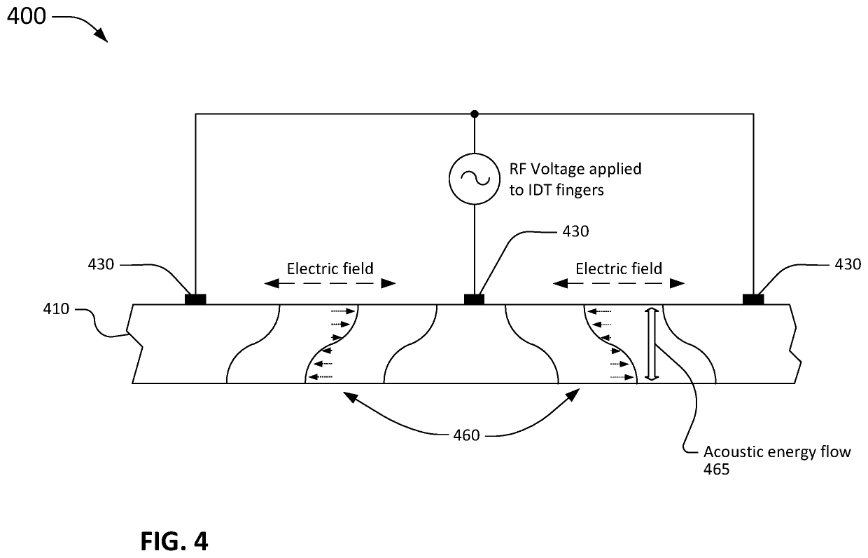

The first and second busbars 132, 134 are configured as the terminals of the XBAR 100. In operation, a radio frequency or microwave signal applied between the two busbars 132, 134 of the IDT 130 primarily excites an acoustic mode within the piezoelectric layer 110. As will be discussed in further detail, the primarily excited acoustic mode is a bulk shear mode or bulk acoustic wave where acoustic energy of a bulk shear acoustic wave is excited in the piezoelectric layer 110 by the IDT 130 and propagates along a direction substantially and/or primarily orthogonal to the surface of the piezoelectric layer 110, which is also primarily normal, or transverse, to the direction of the electric field created by the IDT fingers. That is, when a radio frequency or a microwave signal is applied between the two busbars 132, 134, the RF voltage applied to the respective sets of IDT fingers generates a time-varying electric field that is laterally excited with respect to a surface of the piezoelectric layer 110. Thus, in some cases the primarily excited acoustic mode may be commonly referred to as a laterally excited bulk acoustic wave since displacement, as opposed to propagation, occurs primarily in the direction of the bulk of the piezoelectric layer, as discussed in more detail below in reference to FIG. 4

For purposes of this disclosure, “primarily acoustic mode” may generally refer to as an operational mode in which a vibration displacement is caused in the primarily thickness-shear direction (e.g., X-direction), so the wave propagates substantially and/or primarily in the direction connecting the opposing front and back surfaces of the piezoelectric layer, that is, in the Z direction. In other words, the X-direction component of the wave is significantly smaller than the Z-direction component. The use of the term “primarily” in the “primarily excited acoustic mode” is not necessarily referring to a lower or higher order mode. Thus, the XBAR is considered a transversely excited film bulk wave resonator.

In any event, the IDT 130 is positioned at or on the piezoelectric layer 110 such that at least the fingers of the IDT extend at or on the portion of the piezoelectric layer 110 that is over the cavity 140, for example, the diaphragm 115 as described herein. As shown in FIG. 1, the cavity 140 has a rectangular cross section with an extent greater than the aperture AP and length L of the IDT 130. According to other exemplary aspects, the cavity of an XBAR may have a different cross-sectional shape, such as a regular or irregular polygon. The cavity of an XBAR may have more or fewer than four sides, which may be straight or curved.

According to an exemplary aspect, the area of XBAR 100 is determined as the area of the IDT 130. For example, the area of the IDT 130 can be determined based on the measurement of the length L multiplied by the measurement of the aperture AP of the interleaved fingers of the IDT 130. As used herein through the disclosure, area is referenced in μm² and be considered the area in the X-Y plane of the IDT, for example. Thus, the area of the XBAR 100 may be adjusted based on design choices, as described below, thereby adjusting the overall capacitance of a particular XBAR 100.

For case of presentation in FIG. 1A, the geometric pitch and width of the IDT fingers is greatly exaggerated with respect to the length (dimension L) and aperture (dimension AP) of the XBAR. A typical XBAR has more than ten parallel fingers in the IDT. For example, an XBAR may have hundreds, possibly thousands, of parallel fingers in the IDT according to exemplary aspects. Similarly, the thickness of the fingers in the cross-sectional views is greatly exaggerated.

FIG. 1B shows a schematic cross-sectional view of an alternative XBAR configuration 100′. In FIG. 1B, the cavity 140 (which can correspond generally to cavity 140 of FIG. 1A) of the resonator 100′ is formed entirely within a dielectric layer 124 (for example SiO₂, as in FIG. 1B) that is located between the substrate 120 (indicated as Si in FIG. 1B) and the piezoelectric layer 110 (indicated as LN in FIG. 1B). Although a single dielectric layer 124 is shown having cavity 140 formed therein (e.g., by etching), it should be appreciated that the dielectric layer 124 can be formed by a plurality of separate dielectric layers formed on each other.

Moreover, in the example of FIG. 1B, the cavity 140 is defined on all sides by the dielectric layer 124. However, in other exemplary embodiments, one or more sides of the cavity 140 may be defined by the substrate 120 or the piezoelectric layer 110. In the example of FIG. 1B, the cavity 140 has a trapezoidal shape. However, as noted above, cavity shape is not limited and may be rectangular, oval, or other shapes.

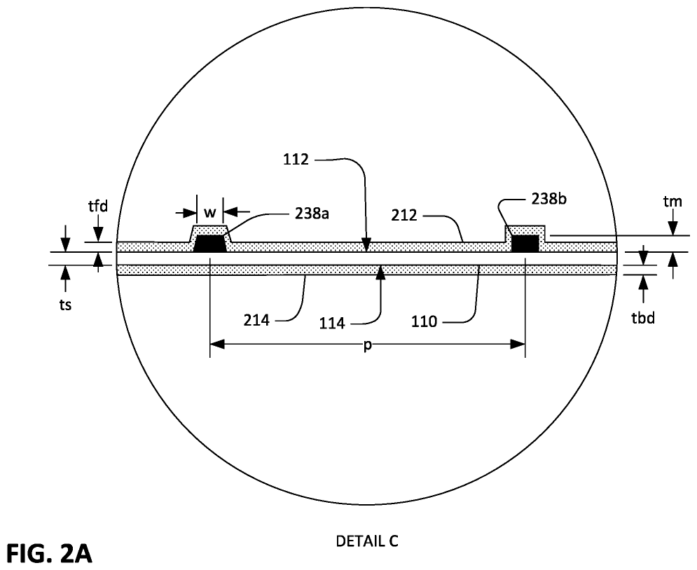

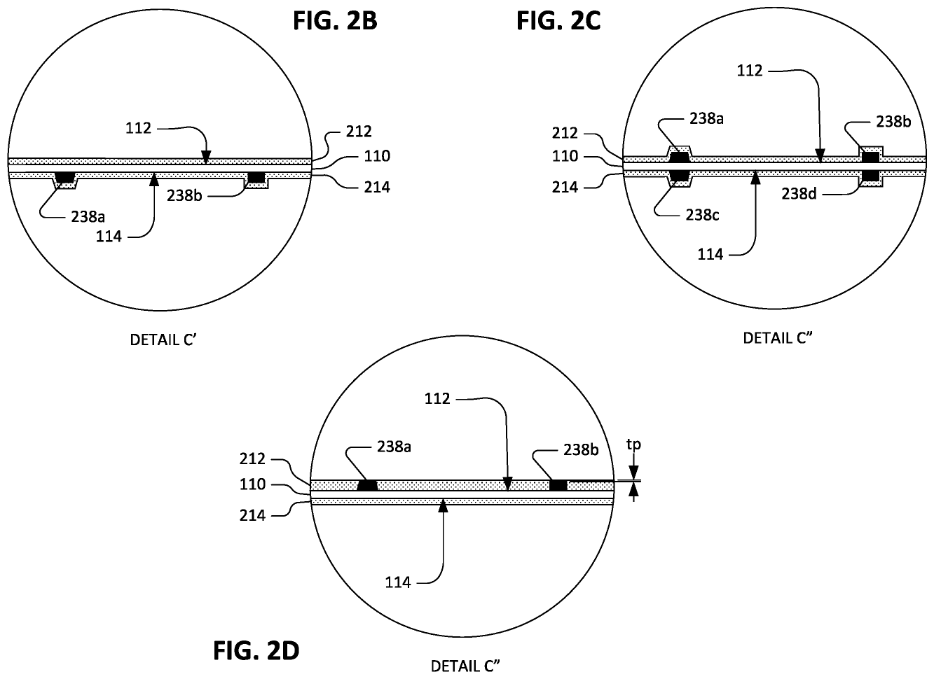

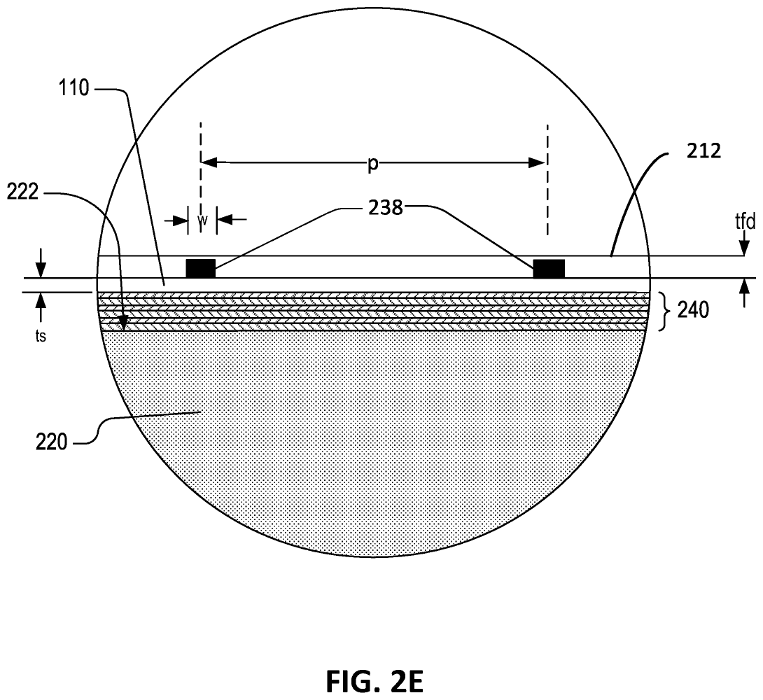

FIG. 2A shows a detailed schematic cross-sectional view of the XBAR 100 of FIG. 1A or 1B. The piezoelectric layer 110 is a single-crystal layer of piezoelectrical material having a thickness ts. ts may be, for example, 100 nm to 1500 nm. When used in filters for 5G NR and Wi-Fi™ bands from 3.4 GHZ to 7 GHZ, the thickness ts may be, for example, 150 nm to 500 nm.

In this aspect, a front side dielectric layer 212 (e.g., a first dielectric coating layer or material) can be formed on the front side 112 of the piezoelectric layer 110. The “front side” of the XBAR is, by definition, the surface facing away from the substrate. The front side dielectric layer 212 has a thickness tfd. As shown in FIG. 2A the front side dielectric layer 212 covers the IDT fingers 238a, 238b, which can correspond to fingers 136 as described above with respect to FIG. 1A. Although not shown in FIG. 2A, the front side dielectric layer 212 may also be deposited only between the IDT fingers 238a, 238b. In this case, an additional thin dielectric layer (not shown) may be deposited over the IDT fingers to seal and passivate the fingers. Further, although also not shown in FIG. 2A, the front side dielectric layer 212 may also be deposited only on select IDT fingers 238a, for example.

A back side dielectric layer 214 (e.g., a second dielectric coating layer or material) can also be formed on the back side of the back side 114 of the piezoelectric layer 110. In general, for purposes of this disclosure, the term “back side” means on a side opposite the conductor pattern of the IDT structure and/or opposite the front side dielectric layer 212. Moreover, the back side dielectric layer 214 has a thickness tbd. The front side and back side dielectric layers 212, 214 may be a non-piezoelectric dielectric material, such as silicon dioxide or silicon nitride. Tfd and tbd may be, for example, 0 to 500 nm. Tfd and tbd may be less than the thickness ts of the piezoelectric layer. Tfd and tbd are not necessarily equal, and the front side and back side dielectric layers 212, 214 are not necessarily the same material. Either or both of the front side and back side dielectric layers 212, 214 may be formed of multiple layers of two or more materials according to various exemplary aspects.

The IDT fingers 238a, 238b may be aluminum, substantially aluminum alloys, copper, substantially copper alloys, beryllium, gold, or some other conductive material. Thin (relative to the total thickness of the conductors) layers of other metals, such as chromium or titanium, may be formed under and/or over the fingers to improve adhesion between the fingers and the piezoelectric layer 110 and/or to passivate or encapsulate the fingers. The busbars (132, 134 in FIG. 1) of the IDT may be made of the same or different materials as the fingers. The cross-sectional shape of the IDT fingers may be trapezoidal (finger 238a), rectangular (finger 238b) or some other shape in various exemplary aspects.

Dimension p is the center-to-center spacing between adjacent IDT fingers, such as the IDT fingers 238a, 238b in FIGS. 2A-2C. Center points of center-to-center spacing may be measured at a center of the width “w” of a finger as shown in FIG. 2A. In some cases, the center-to-center spacing may change if the width of a given finger changes along the length of the finger, if the width and extending direction changes, or any variation thereof. In that case, for a given location along AP, center-to-center spacing may be measured as an average center-to-center spacing, a maximum center-to-center spacing, a minimum center-to-center spacing, or any variation thereof. Adjacent fingers may each extend from a different busbar and center-to-center spacing may be measured from a center of a first finger extending from a first busbar to a center of a second finger, adjacent to the first finger, extending from a second busbar. The center-to-center spacing may be constant over the length of the IDT, in which case the dimension p may be referred to as the pitch of the IDT and/or the pitch of the XBAR. However, according to an exemplary aspect as will be discussed in more detail below, the center-to-center spacing varies along the length of the IDT, in which case the pitch of the IDT may be the average value of dimension p over the length of the IDT. Center-to-center spacing from one finger to an adjacent finger may vary continuously when compared to other adjacent fingers, in discrete sections of multiple adjacent pairs, or any combination thereof. Each IDT finger, such as the IDT fingers 238a, 238b in FIGS. 2A, 2B, and 2C, has a width w measured normal to the long direction of each finger. The width w may also be referred to herein as the “mark.” In general, the width of the IDT fingers may be constant over the length of the IDT, in which case the dimension w may be the width of each IDT finger. However, in an exemplary aspect as will be discussed below, the width of individual IDT fingers varies along the length of the IDT 130, in which case dimension w may be the average value of the widths of the IDT fingers over the length of the IDT. Note that the pitch p and the width w of the IDT fingers are measured in a direction parallel to the length L of the IDT, as defined in FIG. 1A.

In general, the IDT of an XBAR differs substantially from the IDTs used in surface acoustic wave (SAW) resonators, primarily in that IDTs of an XBAR excite a shear thickness mode, as described in more detail below with respect to FIG. 4, where SAW resonators excite a surface wave in operation. Moreover, in a SAW resonator, the pitch of the IDT is one-half of the acoustic wavelength at the resonance frequency. Additionally, the mark-to-pitch ratio of a SAW resonator IDT is typically close to 0.5 (i.e., the mark or finger width is about one-fourth of the acoustic wavelength at resonance). In an XBAR, the pitch p of the IDT is typically 2 to 20 times the width w of the fingers. In addition, the pitch p of the IDT is typically 2 to 20 times the thickness ts of the piezoelectric layer 110. Moreover, the width of the IDT fingers in an XBAR is not constrained to one-fourth of the acoustic wavelength at resonance. For example, the width of XBAR IDT fingers may be 500 nm or greater, such that the IDT can be fabricated using optical lithography. The thickness tm of the IDT fingers may be from 100 nm to about equal to the width w, as the lithography process typically cannot support a configuration where the thickness is greater than the width. The thickness of the busbars (132, 134 in FIG. 1) of the IDT may be the same as, less than, greater than, or any combination thereof, the thickness tm of the IDT fingers. It is noted that the XBAR devices described herein are not limited to the ranges of dimensions described herein.

Moreover, unlike a SAW filter, the resonance frequency of an XBAR is dependent on the total thickness of its diaphragm (i.e., in the vertical or thickness direction), including the piezoelectric layer 110, and the front side and back side dielectric layers 212, 214 disposed thereon. In an exemplary aspect, the thickness of one or both dielectric layers can be varied to change the resonance frequencies of various XBARs in a filter. For example, shunt resonators in a ladder filter circuit may incorporate thicker dielectric layers to reduce the resonance frequencies of the shunt resonators relative to series resonators with thinner dielectric layers, and thus a thinner overall thickness.

Referring back to FIG. 2A, the thickness tfd of the front side dielectric layer 212 over the IDT fingers 238a, 238b may be greater than or equal to a minimum thickness required to deal and passivate the IDT fingers and other conductors on the front side 112 to the piezoelectric layer 110. The minimum thickness may be, for example, 10 nm to 50 nm depending on the material of the front side dielectric layer and method of deposition according to an exemplary aspect. The thickness of the back side dielectric layer 214 may be configured to a specific thickness to adjust the resonance frequency of the resonator as will be described in more detail below.

Although FIG. 2A discloses a configuration in which IDT fingers 238a and 238b are at the front side 112 of the piezoelectric layer 110, alternative configurations can be provided. For example, FIG. 2B shows an alternative configuration in which the IDT fingers 238a, 238b are at the back side 114 of the piezoelectric layer 110 (i.e., facing the cavity) and are covered by a back side dielectric layer 214. A front side dielectric layer 212 may cover the front side 112 of the piezoelectric layer 110. In exemplary aspects, a dielectric layer disposed on the diaphragm of each resonator can be trimmed or etched to adjust the resonant frequency. However, if the dielectric layer is on the side of the diaphragm facing the cavity, there may be a change in spurious modes (e.g., generated by the coating on the fingers). Moreover, with the passivation layer coated on top of the IDTs, the mark changes, which can also cause spurs. Therefore, disposing the IDT fingers 238a, 238b at the back side 114 of the piezoelectric layer 110 as shown in FIG. 2B may eliminate addressing both the change in frequency as well as the effect it has on spurs as compared when the IDT fingers 238a and 238b are on the front side 112 of the piezoelectric layer 110.

FIG. 2C shows an alternative configuration in which IDT fingers 238a, 238b are on the front side 112 of the piezoelectric layer 110 and are covered by a front side dielectric layer 212. IDT fingers 238c, 238d are also on the back side 114 of the piezoelectric layer 110 and are also covered by a back side dielectric layer 214. As previously described, the front side and back side dielectric layer 212, 214 are not necessarily the same thickness or the same material.

FIG. 2D shows another alternative configuration in which IDT fingers 238a, 238b are on the front side 112 of the piezoelectric layer 110 and are covered by a front side dielectric layer 212. The surface of the front side dielectric layer is planarized. The front side dielectric layer may be planarized, for example, by polishing or some other method. A thin layer of dielectric material having a thickness tp may cover the IDT finger 238a, 238b to seal and passivate the fingers. The dimension TP may be, for example, 10 nm to 50 nm.

Each of the XBAR configurations described above with respect to FIGS. 2A to 2D include a diaphragm spanning over a cavity. However, in an alternative aspect, the acoustic resonator can be solidly mounted in which the diaphragm with IDT fingers is mounted on or above a Bragg mirror, which in turn can be mounted on a substrate.

In particular, FIG. 2E shows a detailed schematic cross-sectional view of a solidly mounted XBAR (SM XBAR). The SM XBAR includes a piezoelectric layer 110 and an IDT (including a pair of IDT fingers 238) with a dielectric layer 212 disposed on the piezoelectric layer 110 and IDT fingers 238. The piezoelectric layer 110 has parallel front and back surfaces similar to the configurations described above. Dimension ts is the thickness of the piezoelectric layer 110. The width of the IDT fingers 238 is dimension w, thickness of the IDT fingers is dimension tm, and the IDT pitch is dimension p. It is noted that IDT fingers 238 can generally correspond to fingers 238a and 238b as described above.

In contrast to the XBAR devices shown in FIG. 1, the IDT of an SM XBAR in FIG. 2E is not formed on a diaphragm spanning a cavity in the substrate. Instead, an acoustic Bragg reflector 240 is sandwiched between a surface 222 of the substrate 220 and the back surface of the piezoelectric layer 110. The term “sandwiched” means the acoustic Bragg reflector 240 is both disposed between and mechanically attached to a surface 222 of the substrate 220 and the back surface of the piezoelectric layer 110. In some circumstances, layers of additional materials may be disposed between the acoustic Bragg reflector 240 and the surface 222 of the substrate 220 and/or between the Bragg reflector 240 and the back surface of the piezoelectric layer 110. Such additional material layers may be present, for example, to facilitate bonding the piezoelectric layer 110, the acoustic Bragg reflector 240, and the substrate 220.

The acoustic Bragg reflector 240 may be an acoustic mirror configured to reflect at least a portion of the primary acoustic mode excited in the piezoelectric and includes multiple dielectric layers that alternate between materials having high acoustic impedance and materials having low acoustic impedance. The acoustic impedance of a material is the product of the material's shear wave velocity and density. “High” and “low” are relative terms. For each layer, the standard for comparison is the adjacent layers. Each “high” acoustic impedance layer has an acoustic impedance higher than that of both the adjacent low acoustic impedance layers. Each “low” acoustic impedance layer has an acoustic impedance lower than that of both the adjacent high acoustic impedance layers. As discussed above, the primary acoustic mode in the piezoelectric layer of an XBAR is a shear bulk wave. In an exemplary aspect, each layer of the acoustic Bragg reflector 240 has a thickness equal to, or about, one-fourth of the wavelength in the layer of a shear bulk wave having the same polarization as the primary acoustic mode at or near a resonance frequency of the SM XBAR. Dielectric materials having comparatively low acoustic impedance include silicon dioxide, carbon-containing silicon oxide, and certain plastics such as cross-linked polyphenylene polymers. Materials having comparatively high acoustic impedance include hafnium oxide, silicon nitride, aluminum nitride, silicon carbide. All of the high acoustic impedance layers of the acoustic Bragg reflector 240 are not necessarily the same material, and all of the low acoustic impedance layers are not necessarily the same material. In the example of FIG. 2E, the acoustic Bragg reflector 240 has a total of six layers, but an acoustic Bragg reflector may have more than, or less than, six layers in alternative configurations.

The IDT fingers, such as IDT finger 238a and 238b, may be disposed on a surface of the front side 112 of the piezoelectric layer 110. Alternatively, IDT fingers, such as IDT finger 238a and 238b, may be disposed in grooves formed in the surface of the front side 112. The grooves may extend partially through the piezoelectric layer. Alternatively, the grooves may extend completely through the piezoelectric layer.

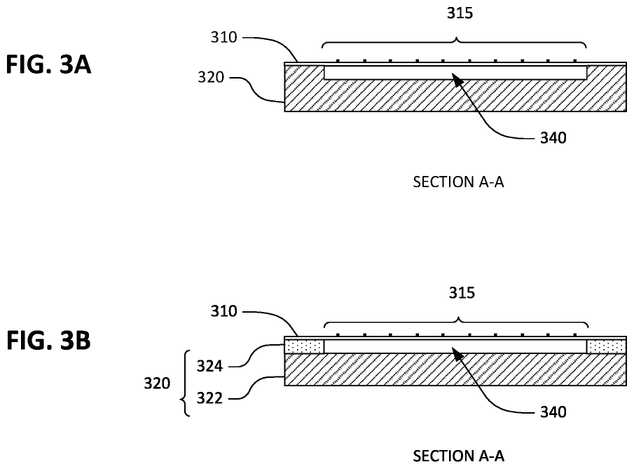

FIG. 3A and FIG. 3B show two exemplary cross-sectional views along the section plane A-A defined in FIG. 1A of XBAR 100. In FIG. 3A, a piezoelectric layer 310, which corresponds to piezoelectric layer 110, is attached directly to a substrate 320, which can correspond to substrate 120 of FIG. 1A. Moreover, a cavity 340, which does not fully penetrate the substrate 320, is formed in the substrate under the portion (i.e., the diaphragm 315) of the piezoelectric layer 310 containing the IDT of an XBAR. The cavity 340 can correspond to cavity 140 of FIGS. 1A and/or 1B in an exemplary aspect. In an exemplary aspect, the cavity 340 may be formed, for example, by etching the substrate 320 before attaching the piezoelectric layer 310. Alternatively, the cavity 340 may be formed by etching the substrate 320 with a selective etchant that reaches the substrate through one or more openings provided in the piezoelectric layer 310.

FIG. 3B illustrates an alternative aspect in which the substrate 320 includes a base 322 and an intermediate layer 324 that is disposed between the piezoelectric layer 310 and the base 322. For example, the base 322 may be silicon (e.g., a silicon support substrate) and the intermediate layer 324 may be silicon dioxide or silicon nitride or some other material, e.g., an intermediate dielectric layer. That is, in this aspect, the base 322 and the intermediate layer 324 are collectively considered the substrate 320. As further shown, cavity 340 is formed in the intermediate layer 324 under the portion (i.e., the diaphragm 315) of the piezoelectric layer 310 containing the IDT fingers of an XBAR. The cavity 340 may be formed, for example, by etching the intermediate layer 324 before attaching the piezoelectric layer 310. Alternatively, the cavity 340 may be formed by etching the intermediate layer 324. In other example embodiments, the cavity 340 may be defined in the intermediate layer 324 by other means from whether the intermediate layer 324 was etched to define the cavity 340. In some cases, the etching may be performed with a selective etchant that reaches the substrate through one or more openings (not shown) provided in the piezoelectric layer 310.

In this case, the diaphragm 315, which can correspond to diaphragm 115 of FIG. 1A, for example, in an exemplary aspect, may be contiguous with the rest of the piezoelectric layer 310 around a large portion of a perimeter of the cavity 340. For example, the diaphragm 315 may be contiguous with the rest of the piezoelectric layer 310 around at least 50% of the perimeter of the cavity 340. As shown in FIG. 3B, the cavity 340 extends completely through the intermediate layer 324. That is, the diaphragm 315 can have an outer edge that faces the piezoelectric layer 310 with at least 50% of the edge surface of the diaphragm 315 coupled to the edge of the piezoelectric layer 310 facing the diaphragm 315. This configuration provides for increased mechanical stability of the resonator.

In other configurations, the cavity 340 may partially extend into, but not entirely through the intermediate layer 324 (i.e., the intermediate layer 324 may extend over the bottom of the cavity on top of the base 322) or may extend through the intermediate layer 324 and into (either partially or wholly) the base 322. As described above, it should be appreciated that the interleaved fingers of the IDT can be disposed on either or both surfaces of the diaphragm 315 in FIGS. 3A and 3B according to various exemplary aspects.

FIG. 4 is a graphical illustration of the primarily excited acoustic mode of interest in an XBAR. FIG. 4 shows a small portion of an XBAR 400 including a piezoelectric layer 410 and three interleaved IDT fingers 430. In general, the exemplary configuration of XBAR 400 can correspond to any of the configurations described above and shown in FIGS. 2A to 2D according to an exemplary aspect. Thus, it should be appreciated that piezoelectric layer 410 can correspond to piezoelectric layer 110 and IDT fingers 430 can be implemented according to any of the configurations of fingers 238a and 238b, for example.

In operation, an RF voltage is applied to the interleaved fingers 430. This voltage creates a time-varying electric field between the fingers. The direction of the electric field is lateral (i.e., laterally excited), or primarily parallel to the surface of the piezoelectric layer 410, as indicated by the arrows labeled “electric field.” Due to the high dielectric constant of the piezoelectric layer 410, the electric field is highly concentrated in the piezoelectric layer relative to the air. The lateral electric field introduces shear deformation in the piezoelectric layer 410, and thus strongly excites a shear acoustic mode, in the piezoelectric layer 410. In this context, “shear deformation” is Defined as deformation in which parallel planes in a material remain parallel and maintain a constant distance while translating relative to each other. In other words, the parallel planes of material are laterally displaced with respect to each other. A “shear acoustic mode” is defined as an acoustic vibration mode in a medium that results in shear deformation of the medium. The shear deformations in the XBAR 400 are represented by the curves 460, with the adjacent small arrows providing a schematic indication of the direction and magnitude of atomic motion. It is noted that the degree of atomic motion, as well as the thickness of the piezoelectric layer 410, have been exaggerated for case of visualization in FIG. 4. While the atomic motions are predominantly lateral (i.e., horizontal as shown in FIG. 4), the direction of acoustic energy flow of the primarily excited shear acoustic mode is substantially and/or primarily orthogonal to the surface of the piezoelectric layer, as indicated by the arrow 465.

An acoustic resonator based on shear acoustic wave resonances can achieve better performance than current state-of-the art film-bulk-acoustic-resonators (FBAR) and solidly-mounted-resonator bulk-acoustic-wave (SMR BAW) devices where the electric field is applied in the thickness direction. In such devices, the acoustic mode is compressive with atomic motions and the direction of acoustic energy flow in the thickness direction. In addition, the piezoelectric coupling for shear wave XBAR resonances can be high (>20%) compared to other acoustic resonators. Thus, high piezoelectric coupling enables the design and implementation of microwave and millimeter-wave filters with appreciable bandwidth.

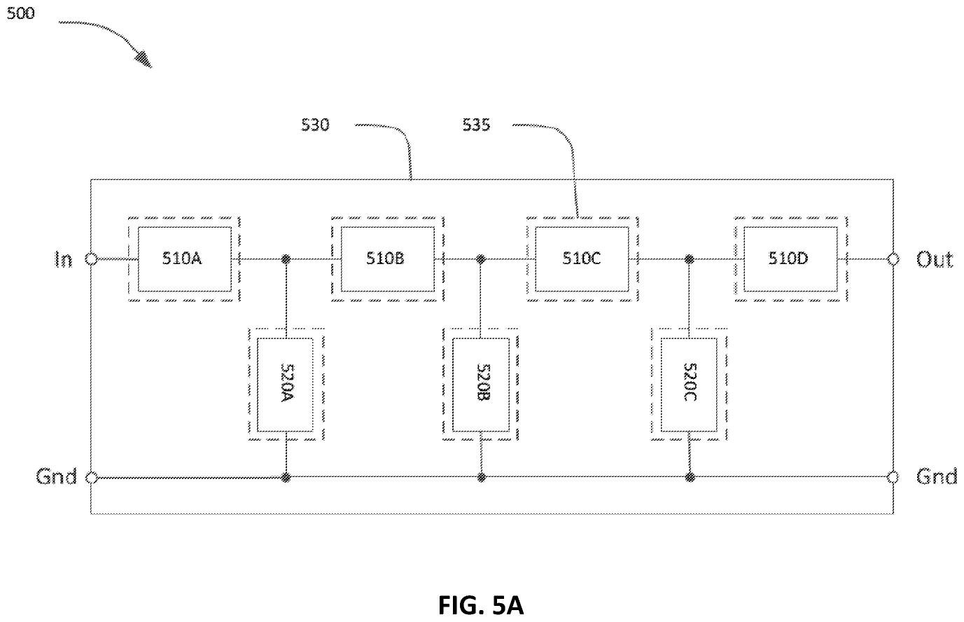

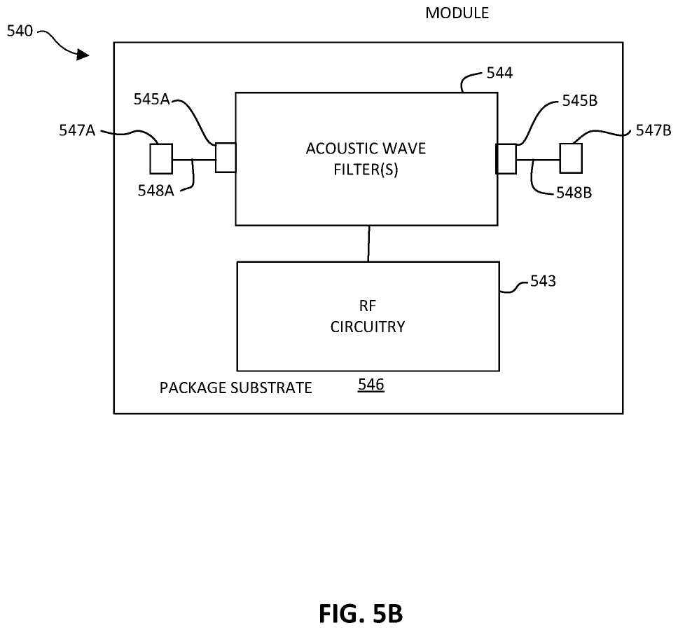

FIG. 5A is a schematic circuit diagram and layout for a high frequency band-pass filter 500 using XBARs, such as the general XBAR configuration 100 described above, for example. The filter 500 has a conventional ladder filter architecture including four resonators 510A, 510B, 510C, and 510D and three shunt resonators 520A, 520B and 520C. The series resonators 510A, 510B, 510C and 510D are connected in series between a first port and a second port (hence the term “series resonator”). In FIG. 5A, the first and second ports are labeled “In” and “Out”, respectively. However, the filter 500 is bidirectional and either port may serve as the input or output of the filter. At least three shunt resonators, such as shunt resonators 520A, 50B and 502C, are connected from nodes between series resonators to a ground connection. A filter may contain additional reactive components, such as inductors, not shown in FIG. 5A. All the shunt resonators and series resonators are XBARs (e.g., either of the XBAR configurations 100 and/or 100′ as discussed above) in the exemplary aspect. The inclusion of three series and two shunt resonators is an example. A filter may have more or fewer than seven total resonators, more or fewer than four series resonators, and more or fewer than three shunt resonators. Typically, all of the series resonators are connected in series between an input and an output of the filter. All of the shunt resonators are typically connected between ground and the input, the output, or a node between two series resonators.

In the exemplary filter 500, the series resonators 510A, 510B, 510C and 510D and the shunt resonators 520A, 520B and 520C of the filter 500 are formed on at least one, and in some cases a single, piezoelectric layer 530 of piezoelectric material bonded to a silicon substrate (not visible). However, in alternative aspects, the individual resonators may each be formed on a separate piezoelectric layer bonded to a separate substrate, for example. Moreover, each resonator includes a respective IDT (not shown), with at least the fingers of the IDT disposed over a cavity, or an acoustic mirror, in the substrate. In this and similar contexts, the term “respective” means “relating things each to each,” which is to say with a one-to-one correspondence. In FIG. 5A, the cavities are illustrated schematically as the dashed rectangles (such as the rectangle 535). In this example, each IDT is disposed over a respective cavity. In other filters, the IDTs of two or more resonators may be disposed over a single cavity.

Each of the resonators 510A, 510B, 510C, 510D, 520A, 520B and 520C in the filter 500 has a resonance where the admittance of the resonator is very high and an anti-resonance where the admittance of the resonator is very low. The resonance and anti-resonance occur at a resonance frequency and an anti-resonance frequency, respectively, which may be the same or different for the various resonators in the filter 500. In simplified terms, each resonator can be considered a short-circuit at its resonance frequency and an open circuit at its anti-resonance frequency. The input-output transfer function will be near zero at the resonance frequencies of the shunt resonators and at the anti-resonance frequencies of the series resonators. In a typical filter, the resonance frequencies of the shunt resonators are positioned below the lower edge of the filter's passband and the anti-resonance frequencies of the series resonators are positioned above the upper edge of the passband.

The frequency range between resonance and anti-resonance frequencies of a resonator corresponds to the coupling of the resonator. Depending on the design parameters of the filter 500, each of the resonators 510A, 510B, 510C, 510D, 520A, 520B and 520C may have a particular coupling parameter to which the respective resonator is tuned in order to achieve the required frequency response of the filter 500.

According to an exemplary aspect, each of the series resonators 510A, 510B, 510C and 510D and the shunt resonators 520A, 520B and 520C can have an XBAR configuration as described above with respect to FIGS. 1-2D in which a diaphragm with IDT fingers spans over a cavity. Alternatively, each of the series resonators 510A, 510B, 510C, 510D and the shunt resonators 520A, 520B, and 520C can have an XBAR configuration in which the series resonators 510A, 510B, 510C, 510D and/or the shunt resonators 520A, 520B, and 520C can be solidly mounted on or above a Bragg mirror (e.g., as shown in FIG. 2E), which in turn can be mounted on a substrate.

FIG. 5B is a schematic diagram of a radio frequency module that includes an acoustic wave filter device according to an exemplary aspect. In particular, FIG. 5B illustrates a radio frequency module 540 that includes one or more acoustic wave filters 544 according to an exemplary aspect. The illustrated radio frequency module 540 also includes radio frequency (RF) circuitry (or circuit) 543. In an exemplary aspect, the acoustic wave filters 544 may include one or more of filter 500 including XBARs, as described above with respect to FIG. 5A.

The acoustic wave filter 544 shown in FIG. 5B includes terminals 545A and 545B (e.g., first and second terminals). The terminals 545A and 545B can serve, for example, as an input contact and an output contact for the acoustic wave filter 544. Although two terminals are illustrated, any suitable number of terminals can be implemented for a particular application. The acoustic wave filter 544 and the RF circuitry 543 are on a package substrate 546 (e.g., a common substrate) in FIG. 5B. The package substrate 546 can be a laminate substrate. The terminals 545A and 545B can be electrically connected to contacts 547A and 547B, respectively, on the package substrate 546 by way of electrical connectors 548A and 548B, respectively. The electrical connectors 548A and 548B can be bumps or wire bonds, for example. In an exemplary aspect, the acoustic wave filter 544 and the RF circuitry 543 may be enclosed together within a common package, with or without using the package substrate 546.

The RF circuitry 543 can include any suitable RF circuitry. For example, the RF circuitry can include one or more radio frequency amplifiers (e.g., one or more power amplifiers and/or one or more low noise amplifiers), one or more radio frequency switches, one or more additional RF filters, one or more RF couplers, one or more delay lines, one or more phase shifters, or any suitable combination thereof. The RF circuitry 543 can be electrically connected to the one or more acoustic wave filters 544. The radio frequency module 540 can include one or more packaging structures to, for example, provide protection and/or facilitate easier handling of the radio frequency module 540. Such a packaging structure can include an overmold structure formed over the package substrate 546. The overmold structure can encapsulate some or all of the components of the radio frequency module 540.

Thus, according to the exemplary aspect, a radio frequency module may incorporate a radio frequency (RF) filter that in turn incorporates multiple XBAR devices connected as a ladder filter circuit. Moreover, the dominant parameter that determines the resonance frequency of an XBAR is the thickness of the piezoelectric layer or membrane (e.g., the diaphragm) of the resonator. Resonance frequency also depends, to a lesser extent, on the pitch and width, or mark, of the IDT fingers. Many filter applications require resonators with a range of resonance and/or anti-resonant frequencies beyond the range that can be achieved by varying the pitch of the IDTs. In an example, U.S. Pat. No. 10,491,291, the contents of which are hereby incorporated by reference, describes the use of a dielectric frequency setting layer deposited between and/or over the fingers of the fingers of the IDTs of shunt resonators to lower the resonant frequencies of the shunt resonators with respect to the resonant frequencies of the series resonators.

The dielectric frequency setting layer thickness required for wide-bandwidth filters facilitates excitation of spurious modes that may be located within the pass-band of the filter. According to exemplary aspects of this disclosure, devices having and methods of forming two (or more) different XBAR piezoelectric layer or membrane (e.g., diaphragm) thicknesses on the same die to tune different frequency primarily shear acoustic modes of the membranes, rather than (or in addition to) using a dielectric frequency setting layer on the piezoelectric layers.

According to an exemplary aspect, XBAR resonators can be formed on the same die with different membrane thicknesses. The resonators may be composite piezoelectric wafers for wideband filters that use a thin bonding layer (e.g., Al₂O₃) to form the different membrane thicknesses. The composite piezoelectric wafer allows two-chip comparable performance of different thickness resonators to be accomplished on a single XBAR die by using two thin piezoelectric layers bonded with the thin bonding layer.

In general, creating different resonator membrane thicknesses on a die may create difficulties to: (1) the difficulty of accurately fabricating more than one membrane thickness, (2) the sensitivity of resonator frequency characteristics to the accuracy of the thickness of their membranes, (3) the sensitivity of resonator characteristics to the acoustic and piezoelectric properties of their membranes, and (4) adverse effects on subsequent IDT, metal, and dielectric processing due to surface elevations created by the different membrane thicknesses.

The exemplary aspects described herein alleviate these difficulties by providing a method for accurately fabricating multiple membrane thicknesses on a die without significantly degrading resonator characteristics (e.g., resonant and anti-resonant frequencies and quality factor of a resonance (Q), spurs, gamma, power handling, temperature coefficient of frequency (TCF)), mechanical or thermal membrane characteristics, and without the different membrane thicknesses that create different elevations on a wafer surface. Using layer transfer subprocesses together with thin etch stop layers as described herein, two membrane thicknesses can be realized on the same wafer without sacrificing membrane performance or planarity of the wafer surface.

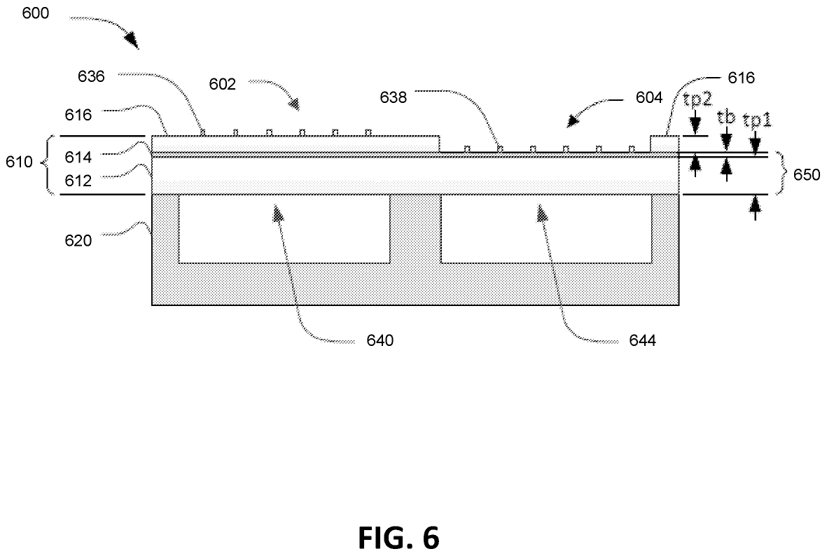

According to an exemplary aspect, FIG. 6 is a schematic cross-sectional view of two XBAR resonators 602 and 604 formed on the same die 600 with different piezoelectric layer (e.g., membrane) thicknesses. Die 600 may be or may be part of a filter device having resonator 602 as lower frequency shunt resonator and resonator 604 as a higher frequency series resonator with respect to the input and output of the filter device. In any case, resonator 602 or 604 can be any of the resonators described herein, for example, the resonators described above with respect to FIGS. 1-2E. For purposes of this disclosure, a “die” may be a semiconductor chip or integrated circuit (IC) chip that is diced from other chips such as of a wafer. It may be a monolithic integrated circuit (also referred to as an IC, a chip, or a microchip) that has a set of electronic circuits on one small flat piece (or “chip”) of semiconductor material that is normally silicon.

Die 600 has substrate 620 having a first cavity 640 and a second cavity 644. A first piezoelectric layer or membrane (e.g., diaphragm) 610 spans the first cavity 640; and a second piezoelectric membrane 650 spans the second cavity 644. The first piezoelectric layer or membrane 610 includes piezoelectric plate 612, bonding layer 614 and piezoelectric plate 616. The second piezoelectric layer or membrane 650 includes piezoelectric plate 612 and bonding layer 614, but not second piezoelectric plate 616. First piezoelectric layer or membrane 610 may include composite layers (or at least two material layers) that correspond to the second piezoelectric plate 616 being chemically or molecularly bonded to the bonding layer 614, which is chemically or molecularly bonded to the first piezoelectric plate 612. The second piezoelectric layer or membrane 650 may be composite layers that include the bonding layer 614 chemically or molecularly bonded to the first piezoelectric plate 612, and the second piezoelectric plate 616 having been masked over the top of resonator 602 and the exposed portion of the second piezoelectric plate 616 having been etched away from the top of resonator 604 using the bonding layer 614 as an etch stop. Effectively, the etch stop layer 614 enable the manufacturing process to control the depth of the etching without needing to consider specific timing constraints for the etching. In one aspect, the etch stop layer can subsequently be removed with a different chemical for the etching process that is gentler on the portion of the piezoelectric layer that has previously been etched away in order to preserve the properties of the piezoelectric layers.

It should be appreciated that while substrate 620 is shown as a single material (e.g., silicon), substrate 620 may be formed as a separate base and intermediate (e.g., dielectric) layer, such as the configuration described above with regard to FIGS. 1B and/or 3B. Moreover, while IDT 636 of acoustic resonator 602 and IDT 638 of acoustic resonator 604 are shown on a surface of the respective piezoelectric layers or membrane opposite the respective cavities 640 and 644, the respective IDTs may be facing the respective cavities 640 and 644 in an alternative aspect.

As shown, the piezoelectric plate 612 has a thickness tp1, which may be in the range of 300 nm to 600 nm, for example. The bonding layer 614 has a thickness tb, which may be in the range of 5 nm to 50 nm, for example. The piezoelectric plate 616 has a thickness tp2, which may be in the range of 50 nm to 200 nm, for example. In some aspects, tp1 is 451, 458 or 465 nm; and tb is 10, 20 or 30 nm, respectively. In some aspects, tp2 can be 120 nm and tm can be 650 nm. In some aspects, tp1 and tp2 are the same. In one case, tp1 and tp2 can both be 197.5 nm. In other aspects, tp1 and tp2 are different, where tp1=465 nm and tp2=120 nm. In some aspects, tp1 can be greater than tp2. In another aspect, tp2 can be greater than tp1. In one aspect, tp1 is 400 nm and the piezoelectric plate 616 does not exist. The piezoelectric plate 612 and/or piezoelectric plate 616 may be a material as noted for the first piezoelectric layer or membrane 610. The piezoelectric plate 612 and piezoelectric plate 616 may the same materials in some implementations or may be different materials or different crystallographic orientations in other implementations. Moreover, the bonding layer may be formed of, or at least include a portion of, Al₂O₃ or SiO₂, for example.

Thus, according to the exemplary aspect shown in FIG. 6, an acoustic resonator (e.g., an XBAR) 600 is provided that includes a substrate 620, which may include at least a pair of cavities 640 and 644. As described above, the cavities 640 and 644 may be provided directly in the substrate 620 (e.g., silicon) or in (or partially in) one or more intermediate layers, which may be dielectric layers, such as silicon dioxide in an exemplary aspect.

Moreover, first piezoelectric layer 612 having first and second surfaces that oppose each other is provided. The first surface may be on a side opposite the substrate 620 and the second surface of the first piezoelectric layer 612 may be coupled or attached to the substrate 620 directly or via one or more intermediate layers. In addition, a second piezoelectric layer 616 having first and second opposing surfaces may be provided opposite the substrate, such that the first surface of the second piezoelectric layer 616 is coupled to the first surface of the first piezoelectric layer 612 and opposite to the substrate 620. That is, the first surfaces of the first piezoelectric layer 612 and the first surface of the second piezoelectric layer 616 face each other.

In addition, an etch stop layer 614, which can be provided as a bonding layer, is disposed between the respective first surfaces of the first and second piezoelectric layers 612 and 616. A first IDT 636 with interleaved fingers and a second IDT 638 with interleaved fingers are disposed at at least one of the first and second piezoelectric layers 612 and 616, respectively. In the example shown in FIG. 6, IDT 636 is disposed on the second piezoelectric layer 616 and IDT 638 is disposed on the first piezoelectric layer 612. As further shown, a portion of one of the first and second piezoelectric layers 612 and 616 is removed between the second surface of the respective piezoelectric layer and the etch stop 614. As described in detail below, the etch stop 614 enables a control of the manufacturing process to effectively prepare two separate resonators 602 and 604 having different thicknesses. That is, the one or more first acoustic resonators 602 has a stack thickness that is different than a stack thickness of the one or more second acoustic resonators 604.

For purposes of this disclosure, the term “stack” as used herein refers to a configuration in the thickness (e.g., Z-axis direction) of the respective resonators. Accordingly, a pair of resonators with the same stack will have the same layers (e.g., piezoelectric, dielectric, substrate), and the like, whereas the acoustic resonators 602 and 604 have a different number of layers, and thus a different stack thickness. According to an exemplary aspect, the one or more series resonators may have a first stack thickness and the one or more shunt resonators may have second stack thickness that is greater than the first stack thickness.

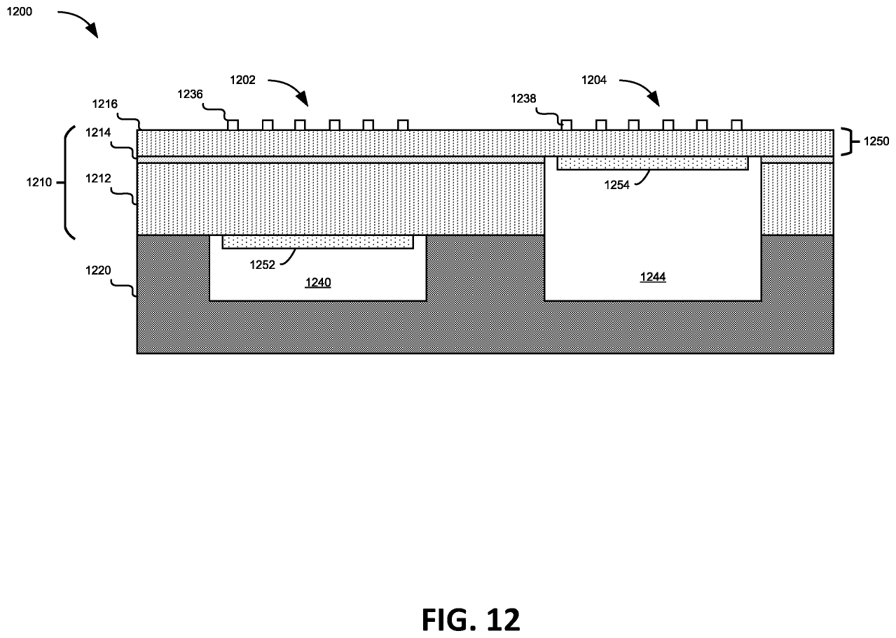

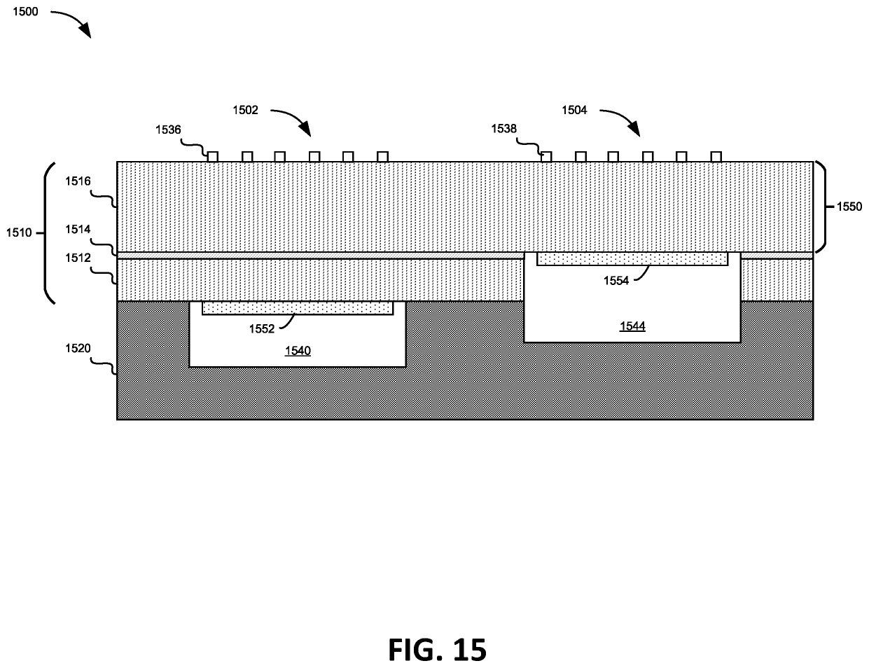

As shown in FIG. 6, the first piezoelectric layer 612 extends over each of the pair of cavities 640 and 644. Moreover, one of the IDTs (e.g., the second IDT 638) is disposed on the first piezoelectric layer 612 where the portion of the second piezoelectric layer 616 is removed. For example, the IDT 638 may be disposed directly on the first piezoelectric layer 612 or on the etch stop layer 614, which may be configured as a bonding layer in an exemplary aspect. As described below with respect to FIGS. 12 and 15, the first and second IDTs may be both disposed on the second surface of the second piezoelectric layer (e.g., second piezoelectric layers 1216 and 1516) in an alternative aspect.

In another exemplary aspect, a material can be used for the etch stop layer 614 such that it is configured as a decoupling dielectric layer, such as that described in U.S. Pat. No. 11,811,386, the contents of which are hereby incorporated by reference. Moreover, the etch stop layer 614 may further comprise a plurality of layers or materials, for example, to separately be configured as an etch stop layer and/or a bonding layer and/or a decoupling dielectric layer as described herein.

As further shown, the portion of the second piezoelectric layer 616 that is removed overlaps one cavity (e.g., cavity 644) of the pair of cavities 640 and 644 in a thickness direction (e.g., the Z axis direction) of the acoustic resonator 604. Effectively, the first and second IDTs 636 and 638 form a pair of acoustic resonators having different resonance frequencies. As described above, the first and second piezoelectric layers 612 and 616 and the first and second IDTs 636 and 638 can be configured such that radio frequency signals applied to each IDT excites a primarily shear acoustic mode in the first and second piezoelectric layers, respectively. Moreover, in an exemplary aspect, the first piezoelectric layer 612 can be formed of a material with a first cut having a first crystallographic orientation, and the second piezoelectric layer 616 can be formed of a material with a second cut having a second crystallographic orientation that is different than the first crystallographic orientation.

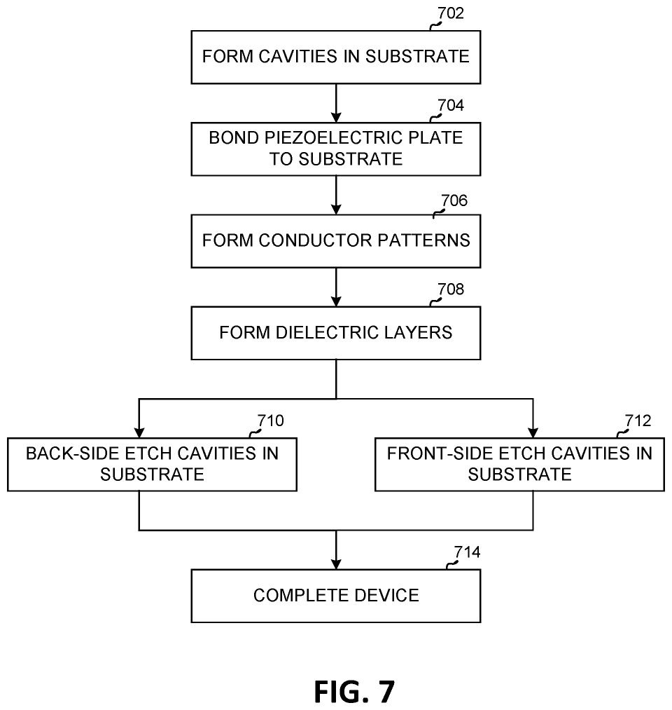

FIG. 7 is a simplified flow chart illustrating a process 700 for fabricating an XBAR or a filter incorporating XBARs. The process 700 will be described with reference to FIG. 6 for case of illustration. The process 700 starts at block 702 with a substrate (e.g., 120 of FIG. 1; 620 of FIG. 6) and a piezoelectric layer or plate (e.g., 110 of FIG. 1; 612, 616 of FIG. 6) of piezoelectric material and terminates at block 714 with a completed XBAR or filter. As will be described subsequently, the piezoelectric layer or plate may be mounted on a sacrificial substrate or may be a portion of wafer of piezoelectric material. It should also be appreciated that the flow chart of FIG. 7 may include only major semiconductor fabrication steps. Various conventional process steps (e.g., surface preparation, chemical mechanical processing (CMP), cleaning, inspection, deposition, photolithography, baking, annealing, monitoring, testing, etc.) may be performed before, between, after, and during the steps shown in FIG. 7.

The flow chart of FIG. 7 captures three variations of the process 700 for fabricating an XBAR, which differ in when and how cavities are formed in the substrate. The cavities may be formed at steps 702, 710, or 712. Only one of these steps is performed in each of the three variations of the process 700.

The piezoelectric plates 612, 616 may be, for example, Z-cut, rotated Z-cut, or rotated Y-cut lithium niobate, lithium tantalate or a material noted for the piezoelectric plates 612, 616. The piezoelectric plates 612, 616 may be some other material and/or some other cut. The substrate 620 may be silicon. The substrate 620 may be some other material that allows formation of deep cavities by etching or other processing. The silicon substrate may have layers of silicon TOX and polycrystalline silicon.

In one implementation of the process 700, at block 702, one or more cavities are formed in the substrate 120, 320, 620 (or a dielectric layer 124 or 324 attached to the substrate) at 702, before the piezoelectric plate 612 is bonded to the substrate 620 directly or via the one or more intermediate layers. A separate cavity may be formed for each resonator in a filter device. The one or more cavities (e.g., 640, 644 of FIG. 6) may be formed using conventional photolithographic and etching techniques. These techniques may be isotropic or anisotropic and may use deep reactive ion etching (DRIE). Typically, the cavities formed at 702 may not penetrate through the substrate 620, and the resulting resonator devices can have a cross-section as shown in FIG. 3 or 6.

At block 704, the piezoelectric plate 612 is bonded to the substrate 620 directly or via the one or more intermediate layers. The piezoelectric plate 612 and the substrate 620 may be bonded by a wafer bonding process. Typically, the mating surfaces of the substrate 620 and the piezoelectric plate 612 are highly polished. As described above, one or more layers of intermediate materials, such as an oxide or metal, may be formed or deposited on the mating surface of one or both of the piezoelectric plate 612 and the substrate 620. One or both mating surfaces may be activated using, for example, a plasma process. The mating surfaces may then be pressed together with considerable force to establish molecular bonds between the piezoelectric plate 612 and the substrate 620 or intermediate material layers.

In a first implementation of 704, the piezoelectric plate 612 is initially mounted on a sacrificial substrate. After the piezoelectric plate 612 and the substrate 620 are bonded, the sacrificial substrate, and any intervening layers, are removed to expose the surface of the piezoelectric plate 612 (the surface that previously faced the sacrificial substrate). The sacrificial substrate may be removed, for example, by material-dependent wet or dry etching or some other process.

In a second implementation of 704, a piezoelectric wafer (e.g., single-crystal) may be used. Ions may be implanted to a controlled depth beneath a surface of the piezoelectric wafer (not shown in FIG. 7). The portion of the piezoelectric wafer from the surface to the depth of the ion implantation is (or will become) the thin piezoelectric plate and the balance of the wafer is effectively the sacrificial substrate. After the implanted surface of the piezoelectric wafer and device substrate are bonded, the piezoelectric wafer may be split at the plane of the implanted ions (for example, using thermal shock), leaving a thin plate of piezoelectric material exposed and bonded to the substrate 620. The thickness of the thin plate piezoelectric material is determined by the energy (and thus depth) of the implanted ions. The process of ion implantation and subsequent separation of a thin plate is commonly referred to as “ion slicing.” The exposed surface of the thin piezoelectric plate may be polished or planarized after the piezoelectric wafer is split.

Bonding the piezoelectric plate 612 at 704 may include descriptions for forming first piezoelectric layer or membrane 610 and second piezoelectric layer or membrane 650 at FIG. 6. The piezoelectric plate 612 bonded to the substrate 620 at 704 may have two (or more) different XBAR piezoelectric membrane (e.g., diaphragm) thicknesses on the same die to tune the membranes, rather than by using a dielectric frequency setting layer on the membranes. The different thicknesses of these piezoelectric layers can be selected to cause selected XBARs to be tuned to different resonant frequencies as compared to the other XBARs. For example, the resonant frequencies of primarily shear acoustic modes of the XBARs in a filter may be tuned using the different thicknesses of these piezoelectric layers.

At block 706, conductor patterns and dielectric layers defining one or more XBAR devices are formed on the surface of the piezoelectric plate. Typically, a filter device can have two or more conductor layers that are sequentially deposited and patterned. The conductor layers may include bonding pads, gold or solder bumps, or other means for making connection between the device and external circuitry. The conductor layers may be, for example, aluminum, an aluminum alloy, copper, a copper alloy, molybdenum, tungsten, beryllium, gold, or some other conductive metal. Optionally, one or more layers of other materials may be disposed below (i.e., between the conductor layer and the piezoelectric plate) and/or on top of the conductor layer. For example, a thin film of titanium, chrome, or other metal may be used to improve the adhesion between the conductor layers and the piezoelectric plate. The conductor layers may include bonding pads, gold or solder bumps, or other means for making connection between the device and external circuitry.

Conductor patterns may be formed at 706 by depositing the conductor layers over the surface of the piezoelectric plate 612 and removing excess metal by etching through patterned photoresist. Alternatively, the conductor patterns may be formed at 706 using a lift-off process. Photoresist may be deposited over the piezoelectric plate and patterned to define the conductor pattern. The conductor layer may be deposited in sequence over the surface of the piezoelectric plate. The photoresist may then be removed, which removes the excess material, leaving the conductor pattern. In some aspects, the forming of conductor layers at 706 may occur prior to the bonding at 704, such as where the IDT fingers 636 are formed prior to bonding the piezoelectric plate 612 to the substrate 620. Forming conductor patterns at 706 may include descriptions for forming the first piezoelectric layer or membrane 610 and/or the second piezoelectric layer or membrane 650 at FIG. 6. As noted above, the IDT fingers 636 and 638 may be formed at either or both surfaces of the respective piezoelectric layers according to various exemplary aspects.

At block 708, a front-side dielectric layer or layers may be formed by depositing one or more layers of dielectric material on the front side of the piezoelectric plate 612, over and between one or more desired conductor patterns of IDT or XBAR devices. The one or more dielectric layers may be deposited using a conventional deposition technique such as sputtering, evaporation, or chemical vapor deposition. The one or more dielectric layers may be deposited over the entire surface of the piezoelectric plate, including on top of the conductor pattern. Alternatively, one or more lithography processes (e.g., using photomasks) may be used to limit the deposition of the dielectric layers to selected areas of the piezoelectric plate, such as only between the interleaved IDT fingers 636. Masks may also be used to allow deposition of different thicknesses of dielectric materials on different portions of the piezoelectric plate 612. In some cases, depositing at 708 includes depositing a first thickness of at least one dielectric layer over the front-side surface of selected IDTs, but no dielectric or a second thickness less than the first thickness of at least one dielectric over the other IDTs. An alternative aspect may be where these dielectric layers are only between the interleaved IDT fingers 636.

According to an exemplary aspect, the different thicknesses of these dielectric layers may cause the selected XBARs to be tuned to different resonant frequencies of the primarily shear acoustic modes as compared to the other XBARs. For example, the resonant frequencies of the XBARs in a filter may be tuned using different front-side dielectric layer thicknesses on some XBARs. The different thicknesses of the piezoelectric plates noted at 704 can be used as a replacement for, or in combination with, having these different thickness dielectric layers to tune the XBARS. As compared to the admittance of an XBAR with tfd=0 (i.e., an XBAR without dielectric layers), the admittance of an XBAR with tfd=30 nm dielectric layer reduces the resonant frequency by about 145 MHz compared to the XBAR without dielectric layers. The admittance of an XBAR with tfd=70 nm dielectric layer reduces the resonant frequency by about 305 MHZ compared to the XBAR without dielectric layers. The admittance of an XBAR with tfd=90 nm dielectric layer reduces the resonant frequency by about 675 MHz compared to the XBAR without dielectric layers. Importantly, the presence of the dielectric layers of various thicknesses has little or no effect on the piezoelectric coupling.

In a second implementation of the process 700, at block 710, one or more cavities are formed in the back side of the substrate 620 (or intermediate dielectric layer) after all the conductor patterns and dielectric layers are formed at 706 and 708, respectively. A separate cavity may be formed for each resonator in a filter device. The one or more cavities may be formed using an anisotropic or orientation-dependent dry or wet etch to open holes through the backside of the substrate 620 to the piezoelectric plate 612. In this case, the resulting resonator devices will have a cross-section as shown in FIG. 1.

In a third implementation of the process 700, at block 712, one or more cavities in the form of recesses in the substrate (or intermediate dielectric layer) may be formed by etching a sacrificial layer formed in the front side of the substrate using an etchant introduced through openings in the piezoelectric plate. A separate cavity may be formed for each resonator in a filter device. The one or more cavities may be formed using an isotropic or orientation-independent dry etch that passes through holes in the piezoelectric plate and etches the recesses in the front-side of the substrate. The one or more cavities formed at 712 may not penetrate completely through the substrate, and the resulting resonator devices may have a cross-section as shown in FIG. 3 or 6. For variations 710 and 712, descriptions above regarding cavities are regarding locations for the cavities, prior to forming the cavities at 710 or 712.

In all variations of the process 700, the filter or XBAR device is completed at 714. Actions that may occur at 714 include depositing an encapsulation/passivation layer such as SiO₂ or Si₃O₄ over all or a portion of the device; forming bonding pads or solder bumps or other means for making connection between the device and external circuitry; excising individual devices from a wafer containing multiple devices; other packaging steps; and testing. Another action that may occur at 714 is to tune the resonant frequencies of the resonators within a filter device by adding or removing metal or dielectric material from the front side of the device. After the filter device is completed at 714, the process ends. FIGS. 1-3 and 6 may show examples of the fingers of selected IDTs after completion at 714.

It should be appreciated that forming the cavities at 710 may require the fewest total process steps but has the disadvantage that the XBAR diaphragms will be unsupported during all of the subsequent process steps. This may lead to damage to, or distortion of, the diaphragms during subsequent processing.

Alternatively, forming the cavities using a back-side etch at 710 requires additional handling inherent in two-sided wafer processing. Forming the cavities from the back side also greatly complicates packaging the XBAR devices since both the front side and the back side of the device must be sealed by the package.

Forming the cavities by etching from the front side at 712 does not require two-sided wafer processing and has the advantage that the XBAR diaphragms are supported during all of the preceding process steps. However, an etching process capable of forming the cavities through openings in the piezoelectric plate will necessarily be isotropic. However, as illustrated in FIG. 3 and FIG. 6, such an etching process using a sacrificial material allows for a controlled etching of the cavity, both laterally (i.e., parallel to the surface of the substrate) as well as normal to the surface of the substrate.

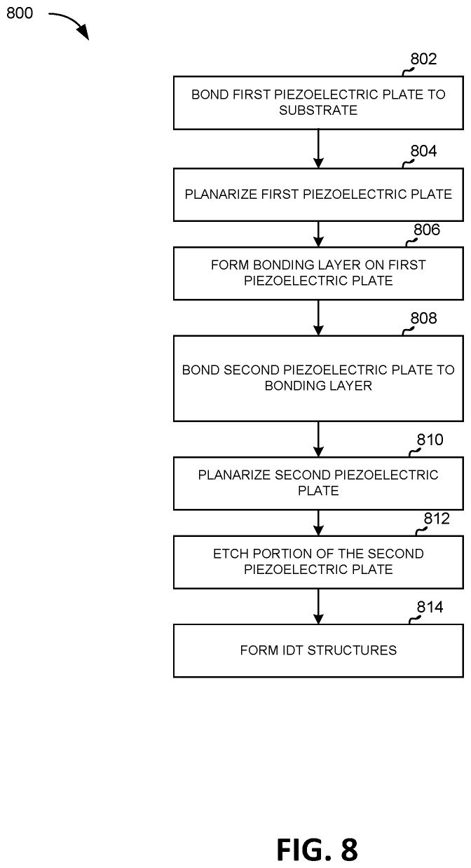

FIG. 8 illustrates a flow chart of a process 800 for fabricating two (or more) different XBAR piezoelectric layer or membrane (e.g., diaphragm) thicknesses on the same die to tune the membranes according to an exemplary aspect. FIG. 8 will be described with reference to corresponding aspects of FIG. 6 for case of illustration. The process 800 starts at 802 in FIG. 8 with a substrate 620 and a first plate of piezoelectric material (e.g., 612). A first piezoelectric plate 612 may be mounted on a sacrificial substrate or may be a portion of wafer of piezoelectric material as previously described. The process 800 ends at 814 in FIG. 8 with a completed XBAR with resonators 602 and 604 formed on the same die. It should be appreciated that the flow chart of FIG. 8 may include only major semiconductor fabrication steps. Various conventional process steps (e.g., surface preparation, cleaning, inspection, deposition, photolithography, baking, annealing, monitoring, testing, etc.) may be performed before, between, after, and during the steps shown in FIG. 8.

At block 802, the first piezoelectric plate 612 is bonded to the substrate 620 either directly or via one or more intermediate layers. Bonding at 802 may be bonding a piezoelectric wafer to a silicon carrier wafer. This bonding may represent or be any of the processes for forming a piezoelectric plate as described above with respect to 704. The first piezoelectric plate 612 and substrate 620 may be materials described for and bonded as noted for any of the plates and substrates as noted herein. Substrate 620 may include prior to bonding or be later etched to form cavities 640 and 644 as shown in FIG. 6. The cavities 640, 644 may be formed by any process noted at 702, 710 or 712.

At 804, the first piezoelectric plate 612 is planarized to form piezoelectric plate 612 having thickness tp1. Planarizing at 804 may be accurately thinning the thickness of a piezoelectric wafer to a thickness of, for example, 665 nm or another thickness of tp1. At 804, the exposed surface of the first piezoelectric plate 612 may be polished or planarized such as using chemical mechanical processing (CMP) from a thickness greater than thickness tp1 as shown at 802, down to a thickness tp1 as shown at 804.

At 806, a bonding layer 614 is formed on the planarized surface of the piezoelectric plate 612. Forming at 806 may be coating a piezoelectric plate interface with a thin bonding layer that is in the range of 2 nm to 5 nm thick and that can act as an etch stop layer for subsequent etching to a piezoelectric plate layer thickness definition. The bonding layer may be, or include at least a portion of, Al₂O₃ or SiO₂, for example. In some cases, it may be any material suitable for molecular bonding to the piezoelectric plate 612 material and to a material of piezoelectric plate 616. Forming at 806 may include blanket depositing the bonding material over all of the exposed top surfaces of the plate using atomic layer deposition (ALD) to form the bonding layer 614. The bonding layer 614 may have a thickness tb and is a material described for bonding layer 614.

At 808, a second piezoelectric plate 616 is bonded to the bonding layer 614. Bonding at 808 may be bonding a piezoelectric wafer to a top surface of the piezoelectric plate 612 using the bonding layer 614. This bonding may represent or be any of the processes for forming a piezoelectric plate noted at 704. The second piezoelectric plate 616 may be a material as noted for any of the plates herein. The bonding of the second piezoelectric plate 616 to the bonding layer 614 may be as described for bonding any of the plates and bonding layers as noted herein. The second piezoelectric plate 616 layer may be bonded using a direct-bond process to the bonding layer 614.

According to exemplary aspects, the crystal-cut orientation of the piezoelectric plates 612 and 616 may be different from one another so that they bond better, couple better and perform better as a dual-wafer (e.g., two piezoelectric plates bonded to together) stack than if they had the same orientation. The difference in crystal-cut orientation of the piezoelectric plates 612 and 616 can be selected for a predetermined performance or tuning of shunt resonators, which may require a thicker piezoelectric dual-wafer plate to operate at a lower frequency than the series resonators.

At 810, the second piezoelectric plate 616 is planarized to form piezoelectric plate 616 having a thickness tp2. Planarizing at 810 may be accurately thinning the thickness of a piezoelectric wafer to a final thickness of, for example, 170 nm or another thickness of tp2. At 810, the exposed surface of the second piezoelectric plate 616 may be polished or planarized such as using chemical mechanical processing (CMP) from a thickness greater than thickness tp2 as shown at 808, down to the thickness tp2 as shown at 810.

At 812, one or more portions of the second piezoelectric plate 616 are etched and removed to form piezoelectric membrane 650 where the plate is etched. Etching at 812 may be masking a wafer having the substrate, and layers (e.g., first piezoelectric plate 612, bonding layer 614 and second piezoelectric plate 616) to protect areas at locations of the shunt resonators 602 and to expose areas at locations of the series resonators 604; then, selectively etching the second piezoelectric plate 616 from the top of the wafer to remove a section of the second piezoelectric plate 616 from over the higher-frequency series resonators on the piezoelectric membrane 650, while leaving the remainder of the second piezoelectric plate 616 unchanged over the lower-frequency shunt resonators on the piezoelectric membrane 610. Etching at 812 may include masking and etching to remove thickness tp2 of the second piezoelectric plate 616 at one or more areas above the cavity 644 to form piezoelectric membrane 650; and to leave thickness tp2 of the second piezoelectric plate 616 unchanged at one or more areas above the cavity 640 to form piezoelectric membrane 610. During the etching process, the bonding layer 614 may function as an etch stop layer that prevents etching damage to the first piezoelectric plate 612 (and to the bonding layer 614) during the etching of the second piezoelectric layer 616 in areas above the high-frequency series resonators on the piezoelectric membrane 650. The bonding layer 614 may function as an etch stop layer in that it may be impervious to and/or etch magnitudes slower than the material of the second piezoelectric plate 616 by the processes and chemicals used to etch the second piezoelectric plate 616. This etching may represent or be any of the processes for removing portions of the second piezoelectric plate 616 to form the piezoelectric membrane 650 as noted herein.

Forming the thinned piezoelectric membrane 650 may include forming a patterned mask layer (e.g., masking) over the second piezoelectric plate 616 at areas where the lower-frequency shunt resonators on the piezoelectric membrane 610 can be formed. The patterned mask may function like an etch stop in that it can be impervious to and/or etch magnitudes slower than the second piezoelectric plate 616 by the processes and chemicals used to etch that plate. Suitable mask layers may include photoresist materials such as a light sensitive material, a light-sensitive organic material (e.g., a photopolymeric, photodecomposing, or photocrosslinking photoresist), or an oxide or a nitride hard mask.

After the mask is patterned, the material of the second piezoelectric plate 616 is etched, and removed where it is not protected by the mask, thus forming the thinned piezoelectric membrane 650. The second piezoelectric plate 616 can be etched, for example, by an anisotropic plasma etching, reactive ion etching, wet chemical etching, and/or other etching technique. The bonding layer 614 may be impervious to or be etched magnitudes slower by the processes and chemicals used to etch second piezoelectric plate 616. After this etch, the photoresist mask is removed from the top surface of second piezoelectric plate 616 to leave the pattern of a desired piezoelectric membrane 610. The remaining material on the wafer includes piezoelectric membranes 610 and 650 as shown.

At 814, IDTs (e.g., IDTs 636 and/or 638) are formed over portions of second piezoelectric plate 616 and bonding layer 614, where the shunt membranes 610 and series membranes 650 are formed, respectively. Forming the IDTs at 814 may create the shunt resonator 602 and series resonator 604 from their respective IDTs and membranes. During forming at 814, the bonding layer 614 may function as an etch stop layer that prevents etching damage to the first piezoelectric plate 612 (and bonding layer 614) during the etching of IDT material from areas within perimeter 145 of the high-frequency series resonators. Forming IDTs at 814 may include descriptions for forming IDTs at 706 of FIG. 7.

Forming the IDTs at 814 may include etch-back processing which commences with blanket depositing IDT conductor material over the exposed top surfaces of the second piezoelectric plate 616 and bonding layer 614. After this depositing, a patterned photoresist mask may be formed over the IDT conductor material at locations or areas where the IDTs will be formed. The photoresist mask may be blanket deposited over the IDT conductor material and then patterned using photolithography to define the conductor pattern at locations where the mask exists after patterning. The patterned photoresist mask may function like an etch stop in that it will be impervious to (and/or be etched magnitudes slower than the conductor material by) the processes and chemicals used to etch the conductor material. Suitable photoresist materials may include a light-sensitive organic material (e.g., a photopolymeric, photodecomposing, or photocrosslinking photoresist).

After the mask is patterned, the IDT conductor material is etched, such as by being dry etched, and removed where it is not protected by the photoresist mask, thus forming the IDT conductor patterns. The conductor layer can be etched, for example, by an anisotropic plasma etching, reactive ion etching, wet chemical etching, and other etching techniques. The etch etches or removes the conductor over and to the second piezoelectric plate 616 over resonator 610 and the bonding layer 614 over resonator 650. Both the second piezoelectric plate 616 and the bonding layer 614 can be a material that is configured to be impervious to (or be etched magnitudes slower by) the processes and chemicals used to etch the conductors. After this etch, the photoresist mask is removed from the top surface of the conductor material to leave the pattern of desired conductor material for the IDTs. The remaining desired conductor material include the IDT conductor and interleaved fingers of IDTs 636 and 638. Process 800 may end at 814 with an XBAR having resonators 602 and 604 formed on the same die 600 with different membrane thicknesses to tune the membranes. In other aspects, the process continues to 708 of FIG. 7, where dielectric layers are formed.

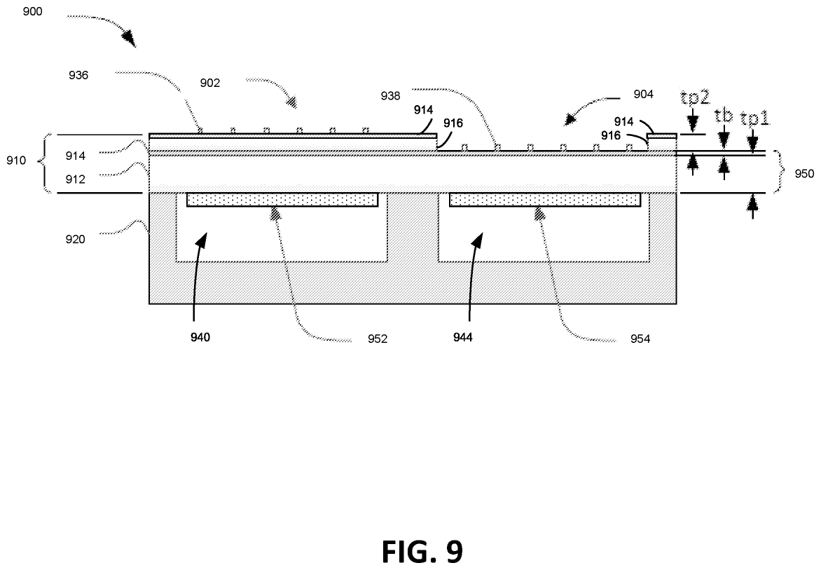

FIG. 9 is a schematic cross-sectional view of a pair of XBAR resonators formed on the same die with different membrane thicknesses using a layer transfer subprocess according to an exemplary aspect. Die 900 has substrate 920 having a first cavity 940 and a second cavity 944. A first piezoelectric layer or membrane (e.g., diaphragm) 910 spans (i.e., is over) the first cavity 940; and a second piezoelectric layer or membrane 950 spans (i.e., is over) the second cavity 944. The first piezoelectric layer or membrane 910 includes piezoelectric plate 912, bonding layer 914 and piezoelectric plate 916. The second piezoelectric layer or membrane 950 includes piezoelectric plate 912 and bonding layer 914, but not second piezoelectric plate 916. In an exemplary aspect, first piezoelectric layer or membrane 910 may include composite layers (or at least two material layers) that correspond to the second piezoelectric plate 916 being chemically or molecularly bonded to the bonding layer 914, which is chemically or molecularly bonded to the first piezoelectric plate 912. Similarly, the second piezoelectric layer or membrane 950 may be composite layers that include the bonding layer 914 chemically or molecularly bonded to the first piezoelectric plate 912, and the second piezoelectric plate 916 having been masked over the top of resonator 902 and the exposed portion of the second piezoelectric plate 916 having been etched away from the top of resonator 904 using the bonding layer 914 as an etch stop.

It should be appreciated that while substrate 920 is shown as a single material (e.g., silicon), substrate 920 may be formed as a separate base and intermediate (e.g., dielectric) layer, such as the configuration described above with regard to FIGS. 1B and/or 3B. Moreover, while IDT 936 of acoustic resonator 902 and IDT 938 of acoustic resonator 904 are shown on a surface of the respective piezoelectric layers or membrane opposite the respective cavities 940 and 944, the respective IDTs may be facing the respective cavities 940 and 944 in an alternative aspect.

The piezoelectric plate 912 has a thickness tp1, which may be in the range of 300 nm to 900 nm. The bonding layer 914 has a thickness tb, which may be in the range of 5 nm to 50 nm. The piezoelectric plate 916 has a thickness tp2, which may be in the range of 50 nm to 200 nm. In some aspects, tp1 is 451, 458 or 465 nm; and tb is 10, 20 or 30 nm, respectively. In some aspects, tp2 can be 120 nm and tm can be 950 nm. In some aspects, tp1 and tp2 are the same. In one case, tp1 and tp2 can both be 197.5 nm. In other aspects, tp1 and tp2 are different, where tp1=465 nm and tp2=120 nm. In some aspects, tp1 can be greater than tp2. In another aspect, tp2 can be greater than tp1. In one aspect, tp1 is 400 nm and the piezoelectric plate 916 does not exist. The piezoelectric plate 912 and/or piezoelectric plate 916 may be a material as noted for the first piezoelectric membrane 910. The piezoelectric plate 912 and piezoelectric plate 916 may the same materials in some implementations or may be different materials in other implementations. The bonding layer may be formed of, or at least include a portion of, Al₂O₃ or SiO₂.

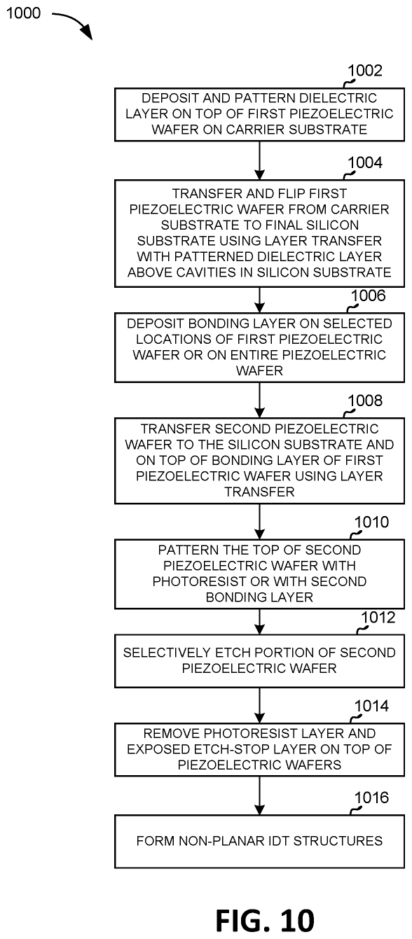

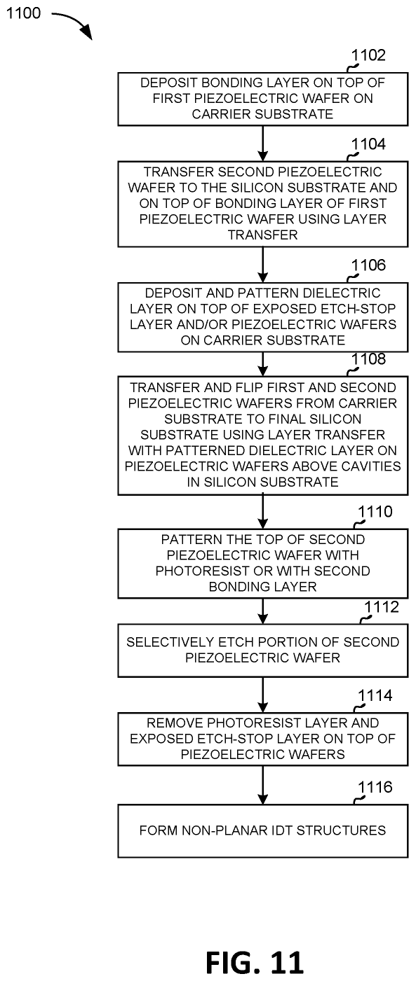

In contrast to die 600 of FIG. 6, the die 900 includes dielectric layers 952 and 954 formed inside of the cavities 940 and 944, respectively. In particular, the dielectric layer 952 is formed on a first portion of a back surface of the first piezoelectric plate 912 that faces the cavity 940, and the dielectric layer 954 is formed on a second portion of the back surface of the first piezoelectric plate 912 that faces the cavity 944. The fabrication of these dielectric layers 952 and 954 can be achieved with a layer transfer subprocess, which will be discussed with reference to FIGS. 10 and 11.

In particular, FIG. 10 is a flow chart of a first process 1000 for fabricating an XBAR with different membrane thicknesses using a layer transfer subprocess according to an exemplary aspect. FIG. 10 will be described with reference to corresponding aspects of FIG. 9 for case of illustration. It should be appreciated that the flow chart of FIG. 10 may include only major semiconductor fabrication steps. Various conventional process steps (e.g., surface preparation, cleaning, inspection, deposition, photolithography, baking, annealing, monitoring, testing, etc.) may be performed before, between, after, and during the steps shown in FIG. 10. The first process 1000 may provide for the transfer of piezoelectric layers one by one to a semiconductor substrate, resulting in a nonplanar piezoelectric surface prior to subsequent IDT metal and oxide/nitride processing.

At 1002, the first process 1000 includes depositing and patterning a dielectric layer (e.g., any desired oxide/nitride layer) on the top of a first piezoelectric wafer on a carrier substrate. With reference to FIG. 9, for example, a dielectric layer may be deposited onto the first piezoelectric plate 912 and patterned into the dielectric layers 952 and 954.

At 1004, the first process 1000 includes transferring and flipping the first piezoelectric wafer from the carrier substrate to the final semiconductor substrate using layer transfer with the patterned dielectric layer positioned immediately above cavities formed in the semiconductor substrate. With reference to FIG. 9, for example, the first piezoelectric plate 912 with the dielectric layers 952 and 954 may be transferred (not shown) and flipped (not shown) onto the substrate 920 such that the dielectric layers 952 and 954 are immediately above the cavities 940 and 944, respectively.

At 1006, the first process 1000 includes depositing a thin bonding layer that serves as piezoelectric etch stop layer on either (a) the membranes intended to be just the single first layer or (b) on the full wafer. In particular, the first process 1000 includes depositing the bonding layer on selected location of the first piezoelectric wafer or on an entire piezoelectric wafer. With reference to FIG. 9, for example, the bonding layer 914 is deposited onto the entire top surface of the first piezoelectric plate 912.

At 1008, the first process 1000 includes transferring a second piezoelectric wafer to the semiconductor substrate and on top of the bonding layer of the first piezoelectric wafer using layer transfer. With reference to FIG. 9, for example, the second piezoelectric plate 916 may be transferred (not shown) onto the top surface of the bonding layer 914.

At 1010, the first process 1000 includes patterning the top surface of the second piezoelectric wafer with photoresist or depositing another thin bonding layer that serves as a second piezoelectric etch stop layer to protect the membranes intended to be two piezoelectric layers thick.

At 1012, the first process 1000 includes etching away the top surface of the second piezoelectric wafer in the areas not protected by the photoresist and/or the second piezoelectric etch stop layer.

At 1014, the first process 1000 includes removing the photoresist and either leaving any exposed etch stop layers on top of the piezoelectric layers or etching them away to expose the piezoelectric layer beneath.

At 1016, the first process 1000 includes proceeding with non-planar IDT formation and other metal and/or dielectric layer processing steps to complete the resonator fabrication. By way of the first process 1000, an XBAR device that includes the die 900 may be realized. Realizing multiple thicknesses using layer transfer can provide better thickness control and result in better acoustic properties in the resonator membranes as opposed to etch subprocesses alone as would be appreciated to one skilled in the art.

FIG. 11 is a flow chart of a second process for fabricating an XBAR with different membrane thicknesses using a layer transfer subprocess according to an exemplary aspect. FIG. 11 will be described with reference to corresponding aspects of FIG. 9 for ease of illustration. It should be appreciated that the flow chart of FIG. 11 may include only major semiconductor fabrication steps. Various conventional process steps (e.g., surface preparation, cleaning, inspection, deposition, photolithography, baking, annealing, monitoring, testing, etc.) may be performed before, between, after, and during the steps shown in FIG. 11. The first process 1100 may provide for the transfer of a dual-stack piezoelectric structure to a semiconductor substrate, resulting in a nonplanar piezoelectric surface prior to subsequent IDT metal and oxide/nitride processing.

At 1102, the second process 1100 includes depositing a thin bonding layer that serves as piezoelectric etch stop layer on selected location of a first piezoelectric wafer mounted on a carrier substrate. With reference to FIG. 9, for example, the bonding layer 914 is deposited onto the entire top surface of the first piezoelectric plate 912, which is bonded to the substrate 920 either directly or via one or more intermediate layers.

At 1104, the second process 1100 includes transferring a second piezoelectric wafer to the semiconductor substrate and on top of the bonding layer of the first piezoelectric wafer using layer transfer. With reference to FIG. 9, for example, the second piezoelectric plate 916 may be transferred (not shown) onto the top surface of the bonding layer 914.

At 1106, the second process 1100 includes depositing and patterning a dielectric layer (e.g., any desired oxide/nitride layer) on the top of a first piezoelectric wafer on a carrier substrate. With reference to FIG. 9, for example, a dielectric layer may be deposited onto the first piezoelectric plate 912 and patterned into the dielectric layers 952 and 954.

At 1108, the second process 1100 includes transferring and flipping the first piezoelectric wafer from the carrier substrate to the final semiconductor substrate using layer transfer with the patterned dielectric layer positioned immediately above cavities formed in the semiconductor substrate. With reference to FIG. 9, for example, the first piezoelectric plate 912 with the dielectric layers 952 and 954 may be transferred (not shown) and flipped (not shown) onto the substrate 920 such that the dielectric layers 952 and 954 are immediately above the cavities 940 and 944, respectively.

At 1110, the second process 1100 includes patterning the top surface of the second piezoelectric wafer with photoresist or depositing another thin bonding layer that serves as a second piezoelectric etch stop layer to protect the membranes intended to be two piezoelectric layers thick.

At 1112, the second process 1100 includes selectively etching away the top surface of the second piezoelectric wafer in the areas that are not protected by the photoresist and/or the second piezoelectric etch stop layer.

At 1114, the second process 1100 includes removing the photoresist and either leaving any exposed etch stop layers on top of the piezoelectric layers or etching them away to expose the piezoelectric layer beneath.

At 1116, the second process 1100 includes proceeding with non-planar IDT formation and other metal and/or dielectric layer processing steps to complete the resonator fabrication. By way of the first process 1100, an XBAR device that includes the die 900 may be realized. Realizing multiple thicknesses using layer transfer can provide better thickness control and result in better acoustic properties in the resonator membranes as opposed to etch subprocesses alone.

FIG. 12 is a schematic cross-sectional view of a pair of XBAR resonators formed on the same die with different membrane thicknesses according to an exemplary aspect. Die 1200 has substrate 1220 having a first cavity 1240 and a second cavity 1244. A first piezoelectric layer or membrane (e.g., diaphragm) 1210 spans the first cavity 1240; and a second piezoelectric layer or membrane 1250 spans the second cavity 1244. In this aspect, the portion of the first piezoelectric layer or membrane 1210 that is removed overlaps and faces second cavity 1244 in the thickness direction of the acoustic resonator. That is, as shown, the first piezoelectric layer or membrane 1210 includes piezoelectric plate 1212, bonding layer 1214 and piezoelectric plate 1216. The second piezoelectric layer or membrane 1250 includes piezoelectric plate 1216 but not the piezoelectric plate 1212 and bonding layer 1214. In an exemplary aspect, first piezoelectric layer or membrane 1210 may include composite layers (or at least two material layers) that correspond to the second piezoelectric plate 1216 being chemically or molecularly bonded to the bonding layer 1214, which is chemically or molecularly bonded to the first piezoelectric plate 1212. Similarly, the second piezoelectric membrane 1250 may be composite layers that include the second piezoelectric plate 1216, and the first piezoelectric plate 1212 having been masked at a location corresponding to that of the resonator 1202 and the exposed portions of the first piezoelectric plate 1212 and the bonding layer 1214 having been etched away, such that the remove portion of the first piezoelectric plate 1212 faces cavity 1244.

It should be appreciated that while substrate 1220 is shown as a single material (e.g., silicon), substrate 1220 may be formed as a separate base and intermediate (e.g., dielectric) layer, such as the configuration described above with regard to FIGS. 1B and/or 3B. Moreover, while IDT 1236 of acoustic resonator 1202 and IDT 1238 of acoustic resonator 1204 are shown on a surface of the respective piezoelectric layers or membrane opposite the respective cavities 1240 and 1244, the respective IDTs may be facing the respective cavities 1240 and 1244 in an alternative aspect. In this aspect, dielectric layers 1252 and 1254 would be disposed on and in between the fingers of the respective IDTs. Moreover, in an exemplary aspect, the thickness (i.e., in the vertical or thickness direction) of dielectric layers 1252 and 1254 can be different from each other to further tune the resonance frequency of the resonators 1202 and 1204. Thus, as shown in FIG. 12, the first dielectric layer 1252 is disposed on the first piezoelectric layer 1212 and facing the first cavity 1240, and the second dielectric layer 1254 is disposed on the second piezoelectric layer 1216 where the portion of the first piezoelectric layer 1212 is removed and facing the second cavity 1244.

In an exemplary aspect, the piezoelectric plate 1212 has a thickness tp1, which may be in the range of 300 nm to 1200 nm. The bonding layer 1214 has a thickness tb, which may be in the range of 5 nm to 50 nm. The piezoelectric plate 1216 has a thickness tp2, which may be in the range of 50 nm to 200 nm. In some aspects, tp1 is 451, 458 or 465 nm; and tb is 10, 20 or 30 nm, respectively. In some aspects, tp2 can be 120 nm and tm can be 1250 nm. In some aspects, tp1 and tp2 are the same. In one case, tp1 and tp2 can both be 197.5 nm. In other aspects, tp1 and tp2 are different, where tp1=465 nm and tp2=120 nm. In some aspects, tp1 can be greater than tp2. In another aspect, tp2 can be greater than tp1. In one aspect, tp1 is 400 nm and the piezoelectric plate 1216 does not exist. The piezoelectric plate 1212 and/or piezoelectric plate 1216 may be a material as noted for the first piezoelectric membrane 1210. The piezoelectric plate 1212 and piezoelectric plate 1216 may the same materials in some implementations or may be different materials in other implementations. The bonding layer may be formed of, or at least include a portion of, Al₂O₃ or SiO₂.

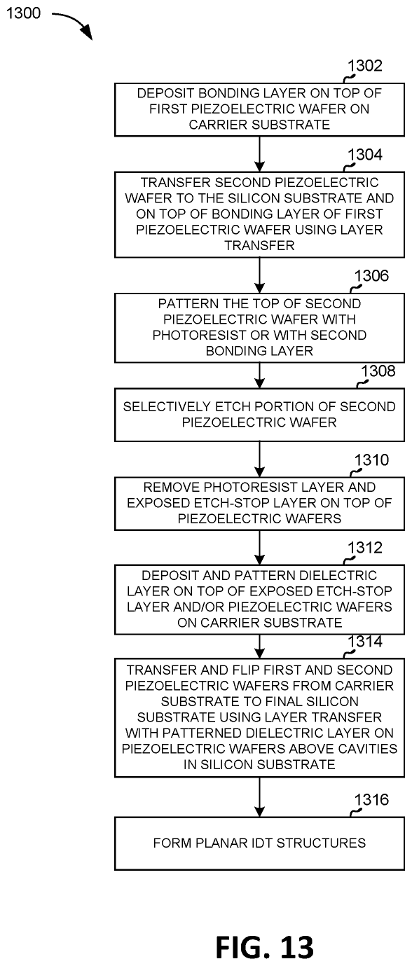

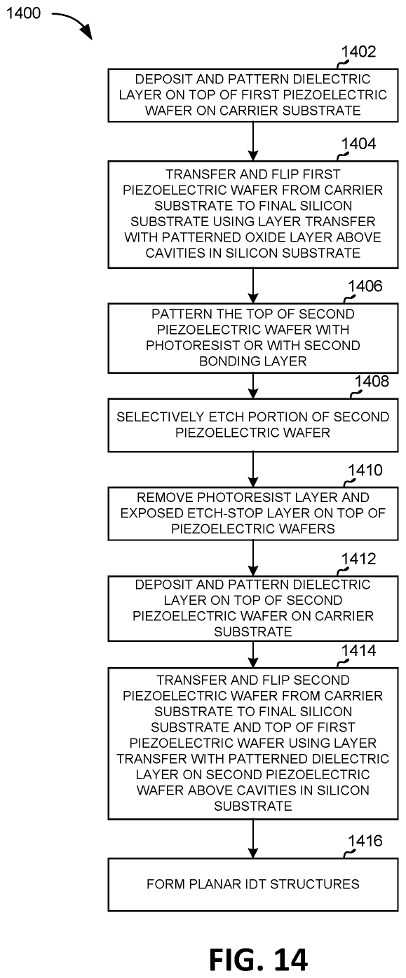

In contrast to die 600 of FIG. 6, the die 1200 includes dielectric layers 1252 and 1254 formed inside of the cavities 1240 and 1244, respectively. Additionally, in contrast to die 900 of FIG. 9, the die 1200 has the resonators 1202 and 1204 both formed on the top surface of the second piezoelectric plate 1216 with the first piezoelectric plate 1212 being etched away underneath the resonator 1204 to thereby define the cavity 1244. In particular, the dielectric layer 1252 is formed on a first portion of a back surface of the first piezoelectric plate 1212 that faces the cavity 1240, and the dielectric layer 1254 is formed on a second portion of the back surface of the first piezoelectric plate 1212 that faces the cavity 1244. The fabrication of these dielectric layers 1252 and 1254 can be achieved with a layer transfer subprocess, which will be discussed with reference to FIGS. 13 and 14.

In particular, FIG. 13 is a flow chart of a third process for fabricating an XBAR with different membrane thicknesses using a layer transfer subprocess according to an exemplary aspect. FIG. 13 will be described with reference to corresponding aspects of FIG. 12 for ease of illustration. It should be appreciated that the flow chart of FIG. 13 may include only major semiconductor fabrication steps. Various conventional process steps (e.g., surface preparation, cleaning, inspection, deposition, photolithography, baking, annealing, monitoring, testing, etc.) may be performed before, between, after, and during the steps shown in FIG. 13. The third process 1300 is a method according to an exemplary aspect that provides for the transfer of a dual-stack piezoelectric structure to a semiconductor substrate, resulting in a planar piezoelectric surface prior to subsequent IDT metal and oxide/nitride processing.

At 1302, the exemplary method includes depositing a thin bonding layer that serves as piezoelectric etch stop layer on selected location of a first piezoelectric wafer mounted on a carrier substrate. With reference to FIG. 12, for example, the bonding layer 1214 is deposited onto the entire top surface of the first piezoelectric plate 1212, which is bonded to the substrate 1220 either directly or via one or more intermediate layers.

At 1304, the method includes transferring a second piezoelectric wafer to a carrier substrate and on top of a bonding layer acting as a piezoelectric etch stop layer using layer transfer. With reference to FIG. 12, for example, the second piezoelectric plate 1216 may be transferred (not shown) onto the top surface of the bonding layer 1214.

At 1306, the method includes patterning the top surface of the second piezoelectric wafer with photoresist or depositing another thin bonding layer that serves as a second piezoelectric etch stop layer to protect the membranes intended to be two piezoelectric layers thick.

At 1308, the method includes selectively etching away the top surface of the second piezoelectric wafer in the areas not protected by the photoresist and/or the second piezoelectric etch stop layer.

At 1310, the method includes removing the photoresist and either leaving any exposed etch stop layers on top of the piezoelectric layers or etching them away to expose the piezoelectric layer beneath.

At 1312, the method includes depositing and patterning a dielectric layer (e.g., any desired oxide/nitride layer) on the top of the exposed piezoelectric etch stop layer and/or on the piezoelectric wafers on the carrier substrate. With reference to FIG. 12, for example, a dielectric layer may be deposited onto the first piezoelectric plate 1212 and patterned into the dielectric layer 1252 and deposited onto the second piezoelectric plate 1216 and patterned into the dielectric layer 1254.

At 1314, the method includes transferring and flipping the first and second piezoelectric wafers from the carrier substrate to the final semiconductor substrate using layer transfer with the nonplanar second piezoelectric wafer at the bottom of the dual-stack and the planar first piezoelectric wafer at the top of the dual-stack with the patterned dielectric layers on the first and second piezoelectric wafers positioned immediately above cavities formed in the semiconductor substrate. With reference to FIG. 12, for example, the first piezoelectric plate 1212 with the dielectric layer 1252 and the second piezoelectric plate 1216 with the dielectric layer 1254 may be transferred (not shown) and flipped (not shown) onto the substrate 1220 such that the dielectric layers 1252 and 1254 are immediately above the cavities 1240 and 1244, respectively.

At 1316, the method includes proceeding with planar IDT formation and other metal and/or dielectric layer processing steps to complete the resonator fabrication. By way of the first process 1300, an XBAR device that includes the die 1200 may be realized. Realizing multiple thicknesses using layer transfer can provide better thickness control and result in better acoustic properties in the resonator membranes as opposed to etch subprocesses alone. In some aspects, the third process 1300 is more beneficial to use for fabricating an XBAR device over the processes 1000 and 1100 because the third process 1300 provides a wafer-wide planar piezoelectric surface that is available for subsequent fabrication processing.

FIG. 14 is a flow chart of a fourth process for fabricating an XBAR with different membrane thicknesses using a layer transfer subprocess layer or. FIG. 14 will be described with reference to corresponding aspects of FIG. 12 for ease of illustration. Tit should be appreciated that the flow chart of FIG. 14 may include only major semiconductor fabrication steps. Various conventional process steps (e.g., surface preparation, cleaning, inspection, deposition, photolithography, baking, annealing, monitoring, testing, etc.) may be performed before, between, after, and during the steps shown in FIG. 14. The fourth process 1400 can be a method according to an exemplary aspect that provides for the transfer of piezoelectric layers one by one to a semiconductor substrate, resulting in a planar piezoelectric surface prior to subsequent IDT metal and oxide/nitride processing.

At 1402, the method includes depositing and patterning a dielectric layer (e.g., any desired oxide/nitride layer) on the top of a first piezoelectric wafer on a carrier substrate. With reference to FIG. 12, for example, a dielectric layer may be deposited onto the first piezoelectric plate 1212 and patterned into the dielectric layers 1252 and 1254.

At 1404, the method further includes transferring and flipping the first piezoelectric wafer from the carrier substrate to the final semiconductor substrate using layer transfer with the patterned dielectric layer on the second piezoelectric wafer positioned immediately above cavities formed in the semiconductor substrate. With reference to FIG. 12, for example, the first piezoelectric plate 1212 with the dielectric layers 1252 and 1254 may be transferred (not shown) and flipped (not shown) onto the substrate 1220 such that the dielectric layers 1252 and 1254 are immediately above the cavities 1240 and 1244, respectively.

At 1406, the method includes patterning the top surface of a second piezoelectric wafer with photoresist or depositing another thin bonding layer that serves as a second piezoelectric etch stop layer to protect the membranes intended to be two piezoelectric layers thick.

At 1408, the method includes etching away the top surface of the second piezoelectric wafer in the areas not protected by the photoresist and/or the second piezoelectric etch stop layer. Next, at 1410, the method includes removing the photoresist and either leaving any exposed etch stop layers on top of the piezoelectric layers or etching them away to expose the piezoelectric layer beneath.

Then, at 1412, a thin bonding layer is deposited that serves as piezoelectric etch stop layer on either: (a) the layers or membranes intended to be just the single first layer or (b) on the full wafer. In particular, the first process 1400 includes depositing the bonding layer on selected location of the first piezoelectric wafer or on an entire piezoelectric wafer. With reference to FIG. 12, for example, the bonding layer 1214 is deposited onto the entire top surface of the first piezoelectric plate 1212.

At 1414, the method includes transferring and flipping the second piezoelectric wafer to the semiconductor substrate and on top of the bonding layer or the top of the first piezoelectric wafer using layer transfer with the patterned dielectric layer on the second piezoelectric wafer positioned immediately above cavities formed in the semiconductor substrate. With reference to FIG. 12, for example, the second piezoelectric plate 1216 may be transferred (not shown) onto the top surface of the bonding layer 1214.

At 1416, the method includes proceeding with planar IDT formation and other metal and/or dielectric layer processing steps to complete the resonator fabrication. By way of the first process 1400, an XBAR device that includes the die 1200 may be realized. Realizing multiple thicknesses using layer transfer can provide better thickness control and result in better acoustic properties in the resonator membranes as opposed to etch subprocesses alone. In some aspects, the fourth process 1400 is more beneficial to use for fabricating an XBAR device over the processes 1000 and 1100 because the fourth process 1400 provides a wafer-wide planar piezoelectric surface that is available for subsequent fabrication processing.

One of the advantages described with reference to FIGS. 13 and 14 is that the remaining two-layer or one-layer piezoelectric membranes do not need to be directly exposed to the piezoelectric etch interface, thus being protected from the piezoelectric etch process by either photoresist or bonding/piezoelectric-etch stop layers (both of which can be removed as configured by an etch process that does not adversely affect the piezoelectric membrane surfaces). Another one of the advantages described with reference to FIGS. 13 and 14 is that with the processes 1300 and 1400, a wafer-wide planar piezoelectric surface is available for subsequent IDT metal and oxide processing. The processes 1300 and 1400 are advantageous since the IDT surface remains planar and the cavity heights are different and can be larger for the thin piezoelectric membranes that are likely to deflect the most under high power use cases, thus lesser likelihood of the piezoelectric membranes bottoming out in the cavities.

FIG. 15 is a schematic cross-sectional view of an alternative XBAR resonator formed on the same die with different membrane thicknesses using either the first process of FIG. 13 or the second process of FIG. 14 according to an exemplary aspect. Die 1500 has substrate 1520 having a first cavity 1540 and a second cavity 1544. A first piezoelectric layer or membrane (e.g., diaphragm) 1510 spans the first cavity 1540; and a second piezoelectric layer or membrane 1550 spans the second cavity 1544. The first piezoelectric membrane 1510 includes piezoelectric plate 1512, bonding layer 1514 and piezoelectric plate 1516. The second piezoelectric membrane 1550 includes piezoelectric plate 1516, but not the second piezoelectric plate 1512 and bonding layer 1514, which have been removed in a similar manner as described above with respect to FIG. 12. In an exemplary aspect, first piezoelectric layer or membrane 1510 may include composite layers (or at least two material layers) that correspond to the second piezoelectric plate 1516 being chemically or molecularly bonded to the bonding layer 1514, which is chemically or molecularly bonded to the first piezoelectric plate 1512. The second piezoelectric layer or membrane 1550 may be composite layers that include the first piezoelectric plate 1512, and the first piezoelectric plate 1512 having been masked at a location corresponding to that of the resonator 1502 and the exposed portions of the first piezoelectric plate 1512 and the bonding layer 1514 having been etched away. In this aspect, the removed portion of resonator 1504 faces cavity 1544.

The piezoelectric plate 1512 has a thickness tp1, which may be in the range of 300 nm to 1500 nm. The bonding layer 1514 has a thickness tb, which may be in the range of 5 nm to 50 nm. The piezoelectric plate 1516 has a thickness tp2, which may be in the range of 50 nm to 200 nm. In some aspects, tp1 is 451, 458 or 465 nm; and tb is 10, 20 or 30 nm, respectively. In some aspects, tp2 can be 150 nm and tm can be 1550 nm. In some aspects, tp1 and tp2 are the same. In one case, tp1 and tp2 can both be 197.5 nm. In other aspects, tp1 and tp2 are different, where tp1=465 nm and tp2=150 nm. In some aspects, tp1 can be greater than tp2. In another aspect, tp2 can be greater than tp1. In one aspect, tp1 is 400 nm and the piezoelectric plate 1516 does not exist. The piezoelectric plate 1512 and/or piezoelectric plate 1516 may be a material as noted for the first piezoelectric membrane 1510. The piezoelectric plate 1512 and piezoelectric plate 1516 may the same materials in some implementations or may be different materials in other implementations. The bonding layer may be formed of, or at least include a portion of, Al₂O₃ or SiO₂.

In contrast to die 900 of FIG. 9, the die 1500 has the resonators 1502 and 1504 both formed on the top surface of the second piezoelectric plate 1516 with the first piezoelectric plate 1512 being etched away underneath the resonator 1504 to thereby define the cavity 1544. Additionally, in contrast to die 1200, the die 1500 has the wall of the cavity 1544 on the substrate 1520 at a different depth than that of the cavity 1244 of FIG. 12. In particular, the dielectric layer 1552 is formed on a first portion of a back surface of the first piezoelectric plate 1512 that faces the cavity 1540, and the dielectric layer 1554 is formed on a second portion of the back surface of the first piezoelectric plate 1512 that faces the cavity 1544. Moreover, in an exemplary aspect, the thickness (i.e., in the vertical or thickness direction) of dielectric layers 1552 and 1554 can be different from each other to further tune the resonance frequency of the resonators 1502 and 1504. That is a thickness of the one or more dielectric layers (e.g., dielectric layer 1552) may be different (e.g., thicker) than the one or more dielectric layers (e.g., dielectric layer 1552). The fabrication of these dielectric layers 1552 and 1554 can be achieved with a layer transfer subprocess, as discussed above with reference to FIGS. 13 and 14.

It should also be appreciated that while substrate 1520 is shown as a single material (e.g., silicon), substrate 1520 may be formed as a separate base and intermediate (e.g., dielectric) layer, such as the configuration described above with regard to FIGS. 1B and/or 3B. Moreover, while IDT 1536 of acoustic resonator 1502 and IDT 1538 of acoustic resonator 1504 are shown on a surface of the respective piezoelectric layers or membrane opposite the respective cavities 1540 and 1544, the respective IDTs may be facing the respective cavities 1540 and 1544 in an alternative aspect.

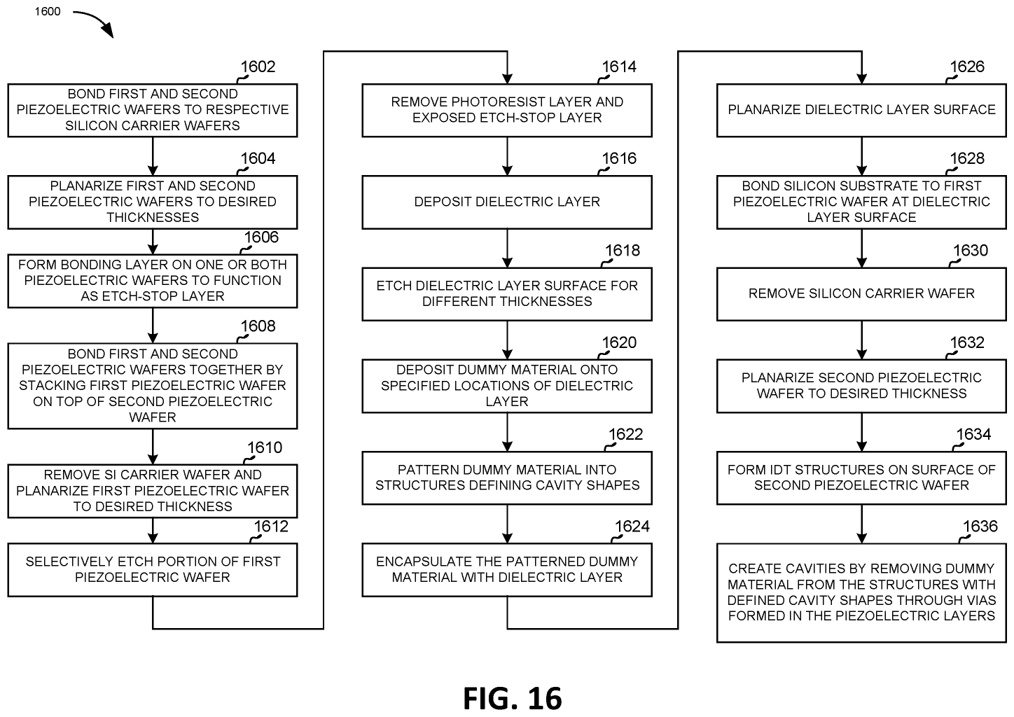

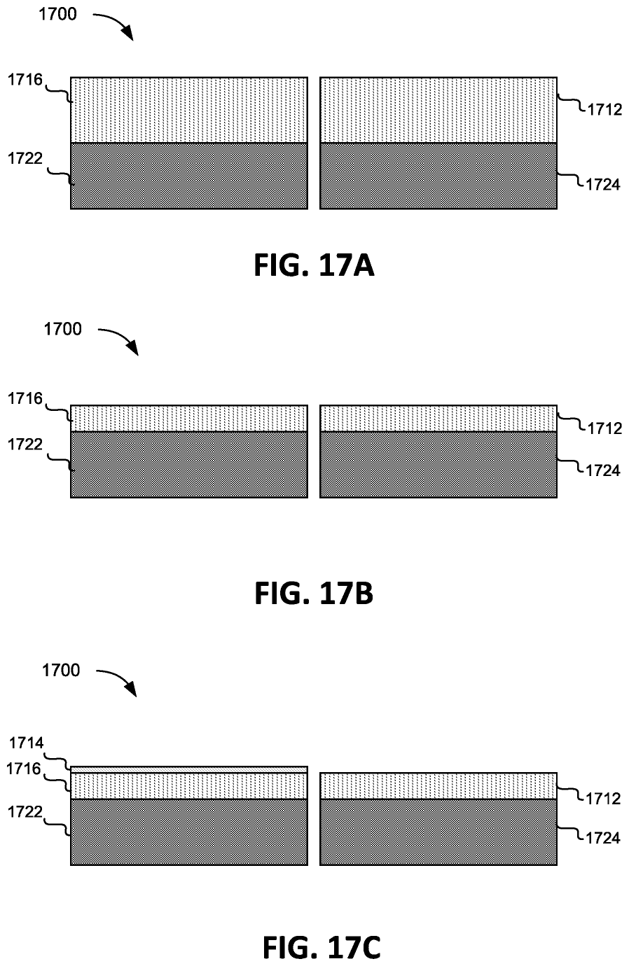

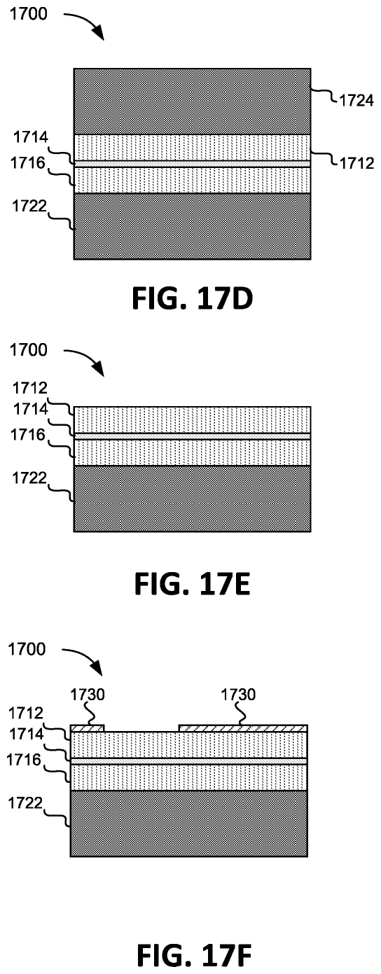

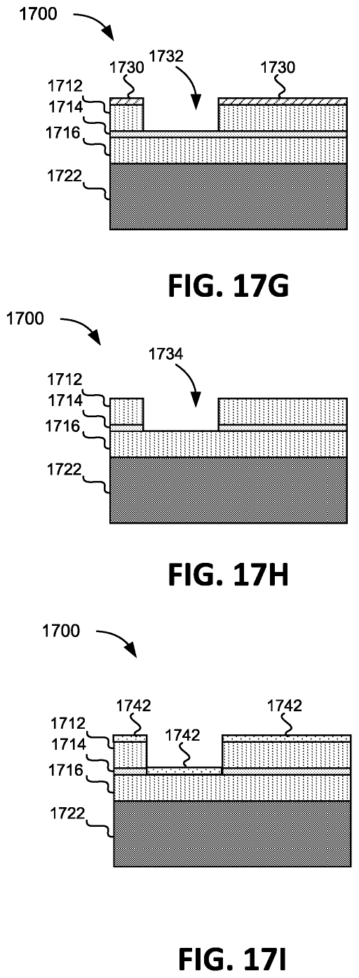

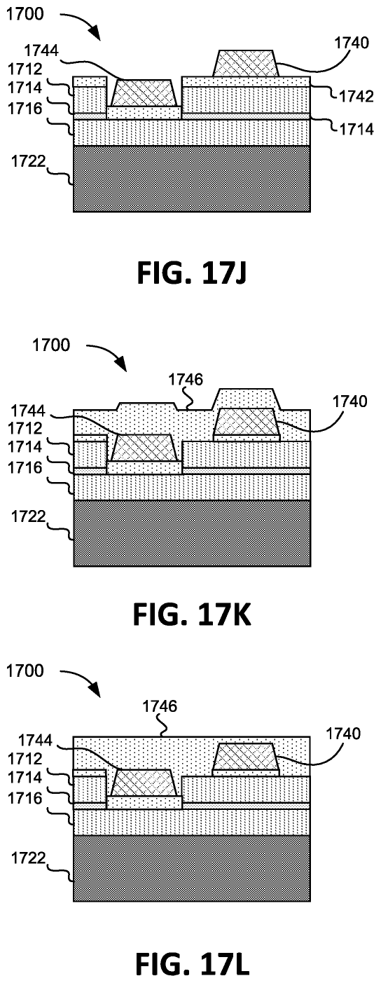

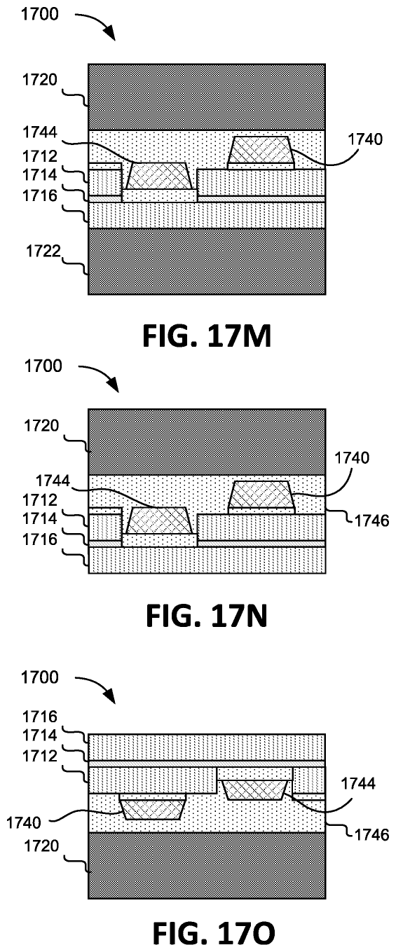

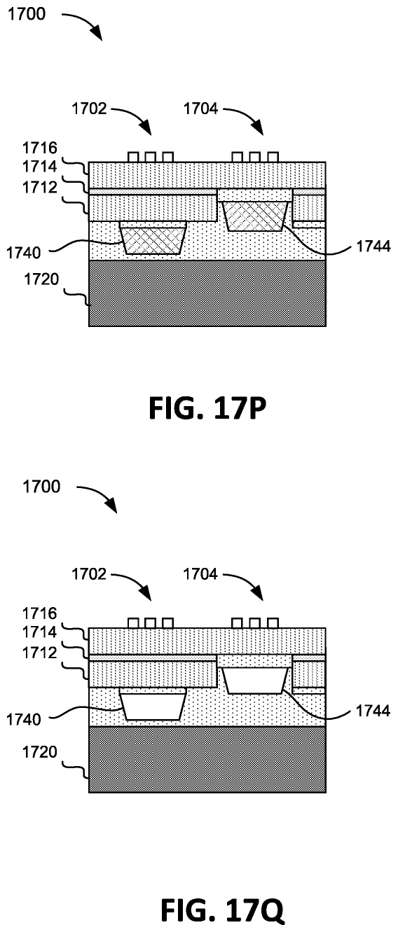

FIG. 16 is a flow chart of an alternative process for fabricating an XBAR with different membrane thicknesses using a layer transfer subprocess according to an exemplary aspect. FIG. 16 will be described with reference to corresponding aspects of FIGS. 17A-17Q for case of illustration. FIGS. 17A-17Q are diagrams illustrating cross-sectional views of an XBAR for fabricating the XBAR resonators on the same die with different membrane thicknesses using the layer transfer subprocess of FIG. 16. The flow chart of FIG. 16 may include only major semiconductor fabrication steps. Various conventional process steps (e.g., surface preparation, cleaning, inspection, deposition, photolithography, baking, annealing, monitoring, testing, etc.) may be performed before, between, after, and during the steps shown in FIG. 16. The fourth process 1600 may provide for the transfer of piezoelectric layers one by one to a semiconductor substrate, resulting in a planar piezoelectric surface prior to subsequent IDT metal and oxide/nitride processing.

At block 1602, first and second piezoelectric wafers can be bonded to respective carrier semiconductor wafers. With reference to FIG. 17A, the first piezoelectric plate 1712 can be bonded to a carrier substrate 1724, and the second piezoelectric plate 1716 can be bonded to a carrier substrate 1722.

At block 1604, the first and second piezoelectric wafers are planarized to a desired thickness by accurately thinning the piezoelectric wafer thicknesses to their required values. For example, the first and second piezoelectric wafers can be planarized from a first thickness of about 360 nm to a thickness of about 100 nm. With reference to FIG. 17B, the first piezoelectric plate 1712 can be planarized down to a thinner thickness. Similarly, the second piezoelectric plate 1716 can be planarized down to a same thinner thickness.

At block 1606, a bonding layer may be formed on the first piezoelectric wafer and/or the second piezoelectric wafer by coating one (or both) of the first and second piezoelectric layer(s) with the thin bonding layer. In some aspects, the bonding layer may be formed of Al₂O₃ or SiO₂, for example. In some aspects, the bonding layer may be thick enough to function as an etch stop layer for subsequent piezoelectric etching/ion milling. With reference to FIG. 17C, the bonding layer 1714 can be formed on the top surface of the second piezoelectric plate 1716.

At block 1608, the first and second piezoelectric wafers may be bonded together by stacking the second piezoelectric wafer on top of the first piezoelectric wafer. With reference to FIG. 17D, the mating surface of the first piezoelectric plate 1712 can be coupled to the top surface of the bonding layer 1714, such that the carrier substrate 1724 and the first piezoelectric plate 1712 are both on top of the second piezoelectric plate 1716 and the carrier substrate 1722, thus creating a dual-stack piezoelectric layer.

At block 1610, the top semiconductor carrier wafer can be removed such that the mating surface of the first piezoelectric wafer is exposed. In this regard, the exposed surface of the first piezoelectric wafer can be planarized by accurately thinning the first piezoelectric wafer to its final thickness. With reference to FIG. 17E, the carrier substrate 1724 coupled to the first piezoelectric plate 1712 is removed, thus exposing the top surface of the first piezoelectric plate 1712. The top surface of the piezoelectric plate 1712 can be reduced down to the desired thickness in an exemplary aspect.

It is noted that the crystal-cut orientation of the first and second piezoelectric wafers can be different from one another in an exemplary aspect so that they can bond better, couple better and perform better as a dual-wafer (e.g., two piezoelectric plates bonded to together) stack than if they had the same orientation. The difference in crystal-cut orientation of the piezoelectric wafers can be selected for a predetermined performance or tuning of XBAR resonators, which may require a thicker piezoelectric dual-wafer plate to operate at a lower frequency.

At block 1612, a photoresist layer (or etch stop layer made of Al₂O₃ or SiO₂, for example) can be added to the top surface of the first piezoelectric wafer to pattern the wafer for single-layer membranes. The etch stop layer can prevent etch damage to the first piezoelectric wafer. Additionally, a top portion of the first piezoelectric wafer can be selectively etched by removing the top portion of the first piezoelectric wafer for higher-frequency resonators while leaving the remainder of the wafer for lower-frequency resonators. With reference to FIG. 17F, a photoresist layer 1730 is formed on the top surface of the first piezoelectric plate 1712 and patterned to leave a portion of the top surface of the piezoelectric plate 1712 exposed.

At block 1614, the exposed portion of the first piezoelectric wafer and not covered by the photoresist layer is removed. With reference to FIG. 17G, the exposed portion of the first piezoelectric plate 1712 that is not covered by the photoresist layer 1730 is selectively removed by an etching process, forming an open cavity 1732. With reference to FIG. 17H, the exposed portion of the bonding layer 1714 is selectively removed by an etching process, forming an open cavity 1734 with the bottom surface of the cavity 1734 exposed to the top surface of the second piezoelectric plate 1716.

At block 1616, a dielectric layer (e.g., SiO₂ or Si₃N₄) is deposited. The dielectric layer can serve as a “backside oxide” on the piezoelectric membranes. With reference to FIG. 17I, a dielectric layer 1742 is deposited into the open cavity 1734 and onto the exposed top surface of the second piezoelectric plate 1716. The dielectric layer 1742 is also deposited onto the top surfaces of the first piezoelectric plate 1712. At block 1618, one or both of the dielectric layer 1742 (which are ultimately provided for the separate acoustic resonators) may be selectively etched to provide for different dielectric thicknesses for temperature compensation and/or adjustment of resonant frequency or coupling of each acoustic resonator.

At block 1620, a dummy material that serves as a sacrificial material (e.g., ZnO) can be deposited onto specified locations of the dielectric layer. At block 1622, the dummy material is patterned into structures defining cavity shapes. With reference to FIG. 17J, the dummy material deposited onto the top surface of the dielectric layer 1742 inside the open cavity 1734 is etched into a first cavity shape structure 1744. The dummy material deposited onto the top surface of the first piezoelectric plate 1712 is etched into a second cavity shape structure 1740. It should be appreciated that this step can be omitted if the intended resonators are solidly-mounted acoustic resonators, such as those described above with respect to FIG. 2E, for example.

At block 1624, the patterned dummy material may be encapsulated with a dielectric material by burying (or implanting) the sacrificial material in SiO₂. With reference to FIG. 17K, the first cavity shape structure 1744 and the second cavity shape structure 1740 are encapsulated with a dielectric material 1746. As illustrated in FIG. 17K, the top surface of the dielectric material 1746 may follow (i.e., conform to) the shapes of the cavities 1740 and 1744 when first deposited. It should also be appreciated that the dielectric material 1746 can correspond to a similar configuration as described above with respect to FIG. 1B and/or 3B, for example.

At block 1626, the dielectric layer surface is planarized by flattening the dielectric layer (e.g., SiO₂) in preparation for a silicon substrate bond. With reference to FIG. 17L, the top dielectric layer surface is planarized to a predetermined distance from the top of the second cavity shape structure 1740.

At block 1628, a semiconductor substrate is bonded to the first piezoelectric wafer at the dielectric layer interface. With reference to FIG. 17M, a semiconductor substrate 1720 is bonded onto the top planarized surface of the dielectric material 1746.

At block 1630, the semiconductor carrier wafer is removed. With reference to FIG. 17N, the carrier substrate 1722 is removed, thus exposing the mating surface of the second piezoelectric plate 1716. With reference to FIG. 17O, the die 1700 is flipped and turned by a layer transfer subprocess, such that the second piezoelectric plate 1716 is now on top of the bonding layer 1714 and the first piezoelectric plate 1712 with the semiconductor substrate 1720 at the bottom.

At block 1632, the second piezoelectric wafer is planarized to its final thickness. With further reference to FIG. 17O, the top surface of the piezoelectric plate 1716 is planarized down to a smaller thickness than that shown in FIG. 17N.

At block 1634, IDT structures and other metal and oxide structures can be formed on the surface of the second piezoelectric wafer by way of subsequent processing steps to complete the resonator fabrication. In some aspects, trim coating thicknesses can be measured and monitored to adjust their respective frequencies. With reference to FIG. 17P, resonators 1702 and 1704 are formed on the top planarized surface of the second piezoelectric plate 1716.

At block 1636, cavities can be formed by removing dummy material from the structures with defined cavity shapes through vias formed in the piezoelectric layers. In some aspects, the vias can be holes that are formed through the piezoelectric layers to expose the sacrificial material, which can then be etched away to create cavities and release the piezoelectric membranes. With reference to FIG. 17Q, the first cavity shape structure 1740 and the second cavity shape structure 1744 become respective cavities after the sacrificial material is removed therein. Additionally, each of the cavities (e.g., 1740, 1744) includes the dielectric layer 1742 formed inside and immediately above its respective cavity. It is noted that this step can be omitted if the intended acoustic resonator is a solidly mounted resonators, such as that described above with respect to FIG. 2E.

In some implementations, the die 900, die 1200 and/or the die 1500 can each be fabricated using the process 1600 and similarly follow the fabrication steps as illustrated in FIGS. 17A-17Q.

Using the process 1600 with layer transfer enables XBAR resonators on the same die to have different membrane thicknesses that are accurately formed. This manufacturing process avoids difficulties in accurately fabricating desired membrane thicknesses; sensitivities of resonator frequency characteristics to the accuracy of the thickness of their membranes; and sensitivities of resonator characteristics to the acoustic and piezoelectric properties of their membranes. Process 1600 solves these problems by accurately fabricating multiple membrane thicknesses on a die without significantly degrading resonator characteristics (e.g., resonant and anti-resonant frequencies and quality factor (Q), spurs, coupling, power handling, temperature coefficient of frequency (TCF)) or mechanical or thermal membrane characteristics. Realizing multiple thicknesses using layer transfer can provide better thickness control and result in better acoustic properties in the resonator membranes as opposed to etch subprocesses alone.

It should be appreciated that the exemplary acoustic resonator devices and manufacturing processes described herein provides several advantages over existing resonator fabrication techniques, including: (1) by providing a simple thickness control of thin piezoelectric layers, (2) the transfer of the thin (fragile) second piezoelectric layer can be performed by a robust/sturdy wafer-to-wafer bonding, (3) all lithography can be performed on the same wafer, so no need to match features on one wafer with those on another wafer when performing a layer transfer subprocess, (4) no etch damage occurs to any piezoelectric layers, (5) an optional dielectric, such as SiO₂ or Si₃N₄, may be provided and may also include an optional backside metal to form metal-insulator-metal (MIM) capacitors with the piezoelectric layer acting as an insulator in some implementations, or may also include a patterned backside formed of SiO₂ and/or a metal for various purposes in other implementations, (6) a planar surface for IDT formation can be obtained, (7) the two-piezoelectric-layer thick membranes can include a different piezoelectric crystal orientation in each layer. Accordingly, the present disclosure provides for acoustic resonators (i.e., XBARs) on the same die to have different piezoelectric membrane thicknesses, with identical or a mix of crystal orientations, without degrading the piezoelectric properties and while preserving wafer planarity.

In general, it is noted that throughout this description, the embodiments and examples shown should be considered as exemplars, rather than limitations on the apparatus and procedures disclosed or claimed. Although many of the examples presented herein involve specific combinations of method acts or system elements, it should be understood that those acts and those elements may be combined in other ways to accomplish the same objectives. With regard to flowcharts, additional and fewer steps may be taken, and the steps as shown may be combined or further refined to achieve the methods described herein. Acts, elements and features discussed only in connection with one embodiment are not intended to be excluded from a similar role in other embodiments.

As used herein, “plurality” means two or more. As used herein, a “set” of items may include one or more of such items. As used herein, whether in the written description or the claims, the terms “comprising”, “including”, “carrying”, “having”, “containing”, “involving”, and the like are to be understood to be open-ended, i.e., to mean including but not limited to. Only the transitional phrases “consisting of” and “consisting essentially of”, respectively, are closed or semi-closed transitional phrases with respect to claims. Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements. As used herein, “and/or” means that the listed items are alternatives, but the alternatives also include any combination of the listed items.

What is claimed:

1. An acoustic resonator, comprising:
a substrate;
a first piezoelectric layer having first and second surfaces that oppose each other, with the second surface facing the substrate and coupled thereto directly or via one or more intermediate layers;
a second piezoelectric layer having first and second opposing surfaces, with the first surface coupled to the first surface of the first piezoelectric layer and opposite to the substrate;
an etch stop layer disposed between the respective first surfaces of the first and second piezoelectric layers; and
first and second interdigital transducers (IDTs) on at least one of the first and second piezoelectric layers, respectively,
wherein a portion of the first piezoelectric layers is removed between the second surface of the first piezoelectric layer and the etch stop.

2. The acoustic resonator according to claim 1, wherein the one or more intermediate layers comprise one or more dielectric layers, and wherein at least a pair of cavities extend partially into the one or more dielectric layers.

3. The acoustic resonator according to claim 2, wherein the first piezoelectric layer extends over each of the pair of cavities.

4. The acoustic resonator according to claim 3, wherein the first IDT is disposed on the second piezoelectric layer where the portion of the first piezoelectric layer is removed.

5. The acoustic resonator according to claim 2, wherein the portion of the first piezoelectric layer that is removed overlaps and faces one of the pair of cavities in a thickness direction of the acoustic resonator.

6. The acoustic resonator according to claim 1, wherein the first and second IDTs form a pair of acoustic resonators having different resonance frequencies.

7. The acoustic resonator according to claim 6, wherein the first and second piezoelectric layers and the first and second IDTs are configured such that radio frequency signals applied to each IDT excites a primarily shear acoustic mode in the first and second piezoelectric layers, respectively.

8. The acoustic resonator according to claim 1, wherein the first piezoelectric layer comprises a material with a first cut having a first crystallographic orientation, and the second piezoelectric layer comprises a material with a second cut having a second crystallographic orientation that is different than the first crystallographic orientation.

9. The acoustic resonator according to claim 1, further comprising at least one dielectric layer on at least one of the first and second piezoelectric layers.

10. The acoustic resonator according to claim 9, wherein the at least one dielectric layer is disposed on and in between interleaved fingers of each of the first and second IDTs, with a thickness of the at least one dielectric layer on the first IDT being different than the at least one dielectric layer on the second IDT.

11. The acoustic resonator according to claim 9, wherein the at least one dielectric layer is disposed on each of the first and second piezoelectric layers and on a side thereof that is opposite to the first and second IDTs, respectively, with a thickness of the at least one dielectric layer on the first piezoelectric layer being different than the at least one dielectric layer on the second first piezoelectric layer.

12. The acoustic resonator according to claim 1, wherein the first and second IDTs are both disposed on the second surface of the second piezoelectric layer.

13. The acoustic resonator according to claim 1, further comprising at least one bonding layer disposed between the first and second IDTs and the at least one of the first and second piezoelectric layers, respectively.

14. The acoustic resonator according to claim 13, wherein the at least one bonding layer comprises the etch stop layer.

15. An acoustic resonator, comprising:
a substrate;
a first piezoelectric layer attached to the substrate via one or more intermediate layers, the piezoelectric layer comprising one or more first acoustic resonators;
a second piezoelectric layer attached to the first piezoelectric layer opposite the substrate and comprising one or more second acoustic resonators;
a first dielectric layer on the first piezoelectric layer;
a second dielectric layer on the second piezoelectric layer;
first and second interdigital transducers (IDTs) at the first and second piezoelectric layers, respectively; and
an etch stop layer disposed between the first and second piezoelectric layers,
wherein a portion of the first piezoelectric layer is removed between the substrate and the etch stop.

16. The acoustic resonator according to claim 15, wherein the first piezoelectric layer is over a first cavity in the one or more intermediate layers and the second piezoelectric layer is over a second cavity in the one or more intermediate layers.

17. The acoustic resonator according to claim 16, wherein the first dielectric layer is disposed on the first piezoelectric layer and facing the first cavity, and the second dielectric layer is disposed on the second piezoelectric layer where the portion of the first piezoelectric layer was removed and facing the second cavity.

18. The acoustic resonator according to claim 15, further comprising:
at least one bonding layer disposed between the first and second IDTs and the at least one of the first and second piezoelectric layers, respectively,
wherein the at least one bonding layer comprises the etch stop layer.

19. The acoustic resonator according to claim 15, wherein the first and second piezoelectric layers and the first and second IDTs are configured such that radio frequency signals applied to each IDT excites a primarily shear acoustic mode in the first and second piezoelectric layers, respectively.

20. A radio frequency module, comprising:
a filter device including a plurality of acoustic resonators; and
a radio frequency circuit coupled to the filter device, the filter device and the radio frequency circuit being enclosed within a common package,
wherein at least one of the plurality of acoustic resonators of the filter device includes:
a substrate;
a first piezoelectric layer having first and second surfaces that oppose each other, with the second surface facing the substrate and coupled thereto directly or via one or more intermediate layers;
a second piezoelectric layer having first and second opposing surfaces, with the first surface coupled to the first surface of the first piezoelectric layer and opposite to the substrate;
an etch stop layer disposed between the respective first surfaces of the first and second piezoelectric layers; and
first and second interdigital transducers (IDTs) on at least one of the first and second piezoelectric layers, respectively,
wherein a portion of the first piezoelectric layer is removed between the second surface of the first piezoelectric layer and the etch stop.
